(19) United States
(12) Patent Application Publication
(10) Pub. No.: US 2004/0245564 A1
(43) Pub. Date: Dec. 9, 2004

(54) Semiconductor storage device, semiconductor device and their manufacturing methods, and portable electronic equipment, and IC card

(76) Inventors: Takayuki Ogura, Nara-shi (JP); Hiroshi Iwata, Ikoma-gun (JP); Akihide Shibata, Nara-shi (JP)

Correspondence Address: BIRCH STEWART KOLASCH & BIRCH, PO BOX 747, FALLS CHURCH, VA, 22040-0747, US

(21) Appl. No.: 10/847,315

(22) Filed: May 18, 2004

(30) Foreign Application Priority Data
May 19, 2003 (JP) P2003-141031

(51) Int. Cl. H01L 29/788

(52) U.S. Cl. 257/315

(57) ABSTRACT

A semiconductor storage device includes a field effect transistor having a gate insulator, a gate electrode and a pair of source/drain diffusion regions which are formed on a semiconductor substrate. Recesses are formed so as to increasingly widening sideways in cross section between opposite side portions of the gate electrode and the semiconductor substrate surface, respectively. Memory function bodies each of which is composed of a charge retention part made of a material having a function of storing electric charge, and an anti-dissipation dielectric having a function of preventing dissipation of stored electric charge, are formed on opposite sides of the gate electrode in such a fashion that the recesses are thereby buried. Thus, the semiconductor storage device is capable of solving the issues of overerase and read failures due to the overerase and enhancing the reliability.

This Nonprovisional application claims priority under 35 U.S.C. §119(a) on Patent Application No. 2003-141031 filed in Japan on May 19, 2003, the entire contents of which are hereby incorporated by reference.

### BACKGROUND OF THE INVENTION

The present invention relates to a semiconductor storage device and its manufacturing method, particularly, an electrically erasable programmable nonvolatile semiconductor storage device and its manufacturing method.

Also, the invention relates to a semiconductor storage device, as well as its manufacturing method, in which semiconductor storage elements and semiconductor switching elements are mounted compositely on one identical substrate.

Also, the invention relates to portable electronic equipment and IC cards equipped with such a semiconductor storage device or semiconductor device.

There have been provided flash memory as an electrically erasable programmable memory device (e.g., see “A handbook for flash memory techniques,” edited by Fujio Masuoka, K. K. Science Forum, Aug. 15, 1993, pp. 55-58). A structural sectional view of an element of a flash memory is shown in FIG. 21. On a semiconductor substrate 901, a floating gate 906 made of polysilicon is provided via a first oxide 904, and a control gate 907 made of polysilicon is provided on the floating gate 906 via a second oxide 905. On a surface of the semiconductor substrate 901 on opposite sides of gate electrodes 906, 907 are formed a pair of source/drain diffusion regions 902, 903. End portions of the gate electrodes 906, 907 are overlapped on end portions of the source/drain diffusion regions 902, 903, respectively. The control gate 907 plays a role as a gate electrode of a FET (Field-Effect Transistor) in flash memory. Between the control gate 907 and the semiconductor substrate 901 are disposed the first oxide 904, the floating gate 906 and a second oxide 905. That is, the flash memory is a memory in which a memory film (floating gate) serving as a charge retention part is disposed at a gate insulator portion of a FET, thereby having a function of changing the threshold voltage of the FET depending on the amount of charge accumulated on the memory film.

The flash memory of this structure has a problem of so-called overerase as described below. That is, an erase operation in flash memory is, normally, to lower the threshold voltage of a FET in the flash memory by pulling off the electrons accumulated at the floating gate or injecting holes thereinto. If this erase is done excessively, the FET would be turned ON due to an effect of the charge retained at the floating gate under the gate electrode (i.e., control gate), causing a current to flow between the source/drain diffusion regions. This phenomenon occurs due to the FET being turned ON only by the retained charge of the floating gate as a result of a structural characteristic that the control gate, which is the gate electrode as a FET, and a floating gate, which is the memory film as a memory, are stacked together.

Upon occurrence of such an overerase, there would arise leakage currents derived from non-selected memory cells in a read operation of the memory cell array, which might cause read failures such as an incidence that currents of selected memory cells could no longer be extracted.

### SUMMARY OF THE INVENTION

Accordingly, an object of the present invention is to provide a semiconductor storage device, as well as its manufacturing method, which is capable of solving the overerase and the problem of read failures due to the overerase.

Another object of the present invention is to provide a semiconductor storage device, as well as its manufacturing method, in which such semiconductor storage elements and semiconductor switching elements forming logic circuits are mounted compositely on one identical substrate.

Still another object of the present invention is to provide portable electronic equipment and IC cards equipped with such a semiconductor storage device or semiconductor device.

In order to achieve the above object, a semiconductor storage device the present invention, comprises:

a field effect transistor which has a gate electrode formed on a semiconductor substrate via a gate insulator and a pair of source/drain diffusion regions formed on a semiconductor substrate surface in ranges corresponding to opposite sides of the gate electrode, wherein

recesses are formed between opposite side portions of the gate electrode and the semiconductor substrate surface so as to be increasingly widening sideways in cross section, respectively, and

memory function bodies each of which is composed of a charge retention part made of a material having a function of storing electric charge, and an anti-dissipation dielectric having a function of preventing dissipation of stored electric charge, are formed on opposite sides of the gate electrode in such a fashion that the recesses are thereby buried.

In this semiconductor storage device, it is implementable that the amount of a current flowing from one of the source/drain diffusion regions to the other of the source/drain diffusion regions upon application of a voltage to the gate electrode can be made changeable depending on a level of electric charge retained in the charge retention parts of the memory function bodies. Since the memory function bodies are formed not at portions of the field effect transistor fulfilling the function of a gate insulator, but at portions beside the gate electrode, in the semiconductor storage device, there can be solved the problems of overerase as well as read failures associated with the overerase, which have been seen in the prior art.

Further, since the memory function bodies are formed in such a fashion that the recesses of the gate electrode are buried, the charge retention parts of the memory function bodies are subject to more influence of the gate electrode. Thus, it becomes implementable to enhance the rewrite speed.

Also, on the assumption that the width of the offset regions (which will be described later) keeps unchanged without being affected by the cross-sectional configuration of gate electrode, since the gate electrode overhangs above the offset regions, the short-channel effect can be suppressed to more extent, allowing a further scale-down to be achieved.

In one embodiment of the semiconductor storage device, the surface of the semiconductor substrate has a flat portion which is opposed to a bottom face of the gate electrode via the gate insulator, slope portions which adjoin opposite sides of the flat portion with respect to a gate length direction to form part of the recesses, and bottom face portions each of which adjoins an outer side of the slope portion.

In the semiconductor storage device of this one embodiment, the distance between a pair of source/drain diffusion regions becomes substantially larger than a distance of planar pattern design. Therefore, deteriorations of transistor operations such as punch-through and short-channel effect due to the scale-down are suppressed. Thus, a semiconductor storage element which is suitable for scale-down can be formed and a semiconductor storage device which allows the manufacturing cost to be suppressed can be provided.

Further, since the voltage of the gate electrode effectively gives an influence on the vicinities of the channels of the memory function bodies from structural reasons, injection and erase of electric charge are easy to achieve. Thus, there can be provided a semiconductor storage device in which write/erase or read failures are suppressed and which is high in reliability.

In one embodiment of the semiconductor storage device, spaces are provided between the bottom face of the gate electrode and the source/drain diffusion regions with respect to the gate length direction.

In the semiconductor storage device of this one embodiment, since spaces (offset regions) are provided between the bottom face of the gate electrode and the source/drain diffusion regions with respect to the gate length direction, a semiconductor storage device which is high in the injection efficiency of electric charge into the memory function bodies and fast in write/erase speed is provided. Further, in the case where the source/drain diffusion regions are disposed at bottom face portions of the semiconductor substrate surface while the gate electrode is positioned on the flat portion of the semiconductor substrate surface, these two members being away from each other via the slope portion, the substantial offset width becomes larger than the offset width on planar pattern design (in the lateral direction). Thus, the distance between a pair of source/drain diffusion regions is scaled down on the design base while enough offset width is maintained. Also, since the gate electrode voltage effectively gives an influence on the offset regions, there can be provided a semiconductor storage device in which the drive current in erasing is large so that misread can be suppressed, and in which the read speed is fast.

In one embodiment, there is provided a semiconductor storage device in which the topmost position of the charge retention part is below the topmost position of the gate electrode.

In the semiconductor storage device of this one embodiment, the charge retention part can be disposed limitedly is the vicinities of the channel. Therefore, since electrons to be injected by writing are limited to the vicinities of the channel, it becomes easier to remove the electrons by erasing. Thus, erase failures can be suppressed. Also, since areas occupied by the charge retention part are limited, the electron density becomes higher on condition that the number of injected electrons is unchanged. Therefore, write/erase operations of electrons can be achieved efficiently, and a semiconductor storage device of high write/erase speed can be formed.

In one embodiment of the semiconductor storage device, a side face of the gate electrode has a flat portion generally vertical to a surface of the gate insulator, and a slope portion which adjoins an underside of this flat portion to form part of the recesses, and the anti-dissipation dielectric includes a first dielectric which covers the flat portion and the slope portion of the side face of the gate electrode as well as the slope portions and the bottom face portions of the semiconductor substrate surface, at a substantially uniform film thickness, in such a manner that the charge retention part and the gate electrode, as well as the charge retention part and the semiconductor substrate, are thereby isolated from each other, respectively.

In the semiconductor storage device of this one embodiment, since the anti-dissipation dielectric is separate from the gate electrode and the semiconductor substrate via the first dielectric, dissipation of electric charge retained in the charge retention part to the gate electrode and the semiconductor substrate is suppressed. Accordingly, the retention characteristic is improved to a great extent. Further, in the case where the thickness of the first dielectric is a generally uniform thickness within a range of 1 nm to 10 nm, since the thickness of a dielectric that isolates the semiconductor substrate and the charge retention part as well as the gate electrode and the charge retention part, from each other is not less than 1 nm, dissipation of electric charge can be prevented so that the retention is improved, and by the thickness of being not more than 10 nm, electric charge can be injected with high efficiency. Furthermore, not less than 3 nm thicknesses of the first dielectric make it possible to suppress the dissipation of electric charge by direct tunneling, and those of 6 nm make it possible to efficiently move the electric charge by tunnel conduction such as FN tunnel conduction between the semiconductor substrate and the fine particles as well as between the gate electrode and the fine particles. Thus, there can be provided a semiconductor storage device which is capable of high-speed write/erase operations with quite low voltage and long-term retention.

It is noted here that the terms, “substantially uniform” and “generally uniform,” means being within manufacture variations.

In one embodiment of the semiconductor storage device, the semiconductor substrate is a silicon substrate, and materials of the gate insulator, the gate electrode, the first dielectric and the charge retention part are silicon compounds.

In the semiconductor storage device of this one embodiment, with the use of silicon or silicon compounds, which are widely used as the material of LSIs, it becomes practicable to employ quite highly advanced silicon processes. Thus, the manufacture is facilitated.

In one embodiment of the semiconductor storage device, at least part of the charge retention part is overlapped with part of the source/drain diffusion regions.

In the semiconductor storage device of this one embodiment, the current value of reading of the semiconductor storage device is greatly improved, compared with the case where there is no such overlap. As a result, the read speed is also greatly improved, so that a semiconductor storage device of high read speed is provided.

In one embodiment of the semiconductor storage device, the charge retention part has a portion generally parallel to the surface of the gate insulator.

In the semiconductor storage device of this one embodiment, the likeliness that an inverted layer may be formed at the offset region can effectively be controlled depending on the amount level of electric charge stored in the charge retention part, and therefore the memory effect can be increased. Further, the memory effect can be maintained less changed even with the offset amount varied, so that variations of the memory effect can be suppressed.

In one embodiment of the semiconductor storage device, a side face of the gate electrode has a flat portion generally vertical to a surface of the gate insulator, and a slope portion which adjoins an underside of this flat portion to form part of the recesses, and

the charge retention part includes a portion extending generally parallel to the flat portion of the side face of the gate electrode.

In the semiconductor storage device of this one embodiment, electric charge to be injected into the charge retention part in rewriting is increased, so that the rewrite speed is increased.

In one embodiment of the semiconductor storage device, a thickness of a portion of the anti-dissipation dielectric that isolates the charge retention part and the semiconductor substrate from each other is thinner than a film thickness of the gate insulator and not less than 0.8 nm.

In the semiconductor storage device of this one embodiment, the injection of electric charge into the charge retention part becomes easier to achieve, so that the voltage for write operation or erase operation can be lowered, or that the speed of write operation and erase operation can be made higher. Also, since the amount of induced to the channel formation region or well region upon electric charge retention into the charge retention part is increased, so that the memory effect can be increased.

Further, since the thickness of the portion that isolates the charge retention part and the semiconductor substrate from each other is not less than 0.8 nm, considerable deteriorations of the retention characteristic is suppressed.

In one embodiment of the semiconductor storage device, a thickness of a portion of the anti-dissipation dielectric that isolates the charge retention part and the semiconductor substrate from each other is thicker than a film thickness of the gate insulator and not more than 20 nm.

In the semiconductor storage device of this one embodiment, it becomes possible to improve the retention characteristic without worsening the short-channel effect of the memory.

Further, since the thickness of the portion that isolates the charge retention part and the semiconductor substrate is not more than 20 nm, decreases in the rewrite speed can be suppressed.

In one embodiment of the semiconductor storage device, at least part of the source/drain diffusion regions is disposed in the slope portion of the semiconductor substrate surface.

In the semiconductor storage device of this one embodiment, hot carriers in the injection of electric charge into the memory function bodies can efficiently be generated at the swelling portion formed by the flat portion and the slope portions of the semiconductor substrate surface. As a result, electric charge is efficiently injected from the slope portions into the memory function bodies. Thus, a higher rewrite speed is achieved.

In one embodiment of the semiconductor storage device, inside the pair of source/drain diffusion regions, counter regions which are doped more heavily than a channel formation region located just under the bottom face of the gate electrode are formed with a conductive type reverse to that of the source/drain diffusion regions.

In the semiconductor storage device of this one embodiment, the generation efficiency of hot carriers in the injection of electric charge into the memory function bodies can be enhanced, and further the short-channel effect such as punch-through can be suppressed.

In one embodiment of the semiconductor storage device, the source/drain diffusion regions each have an extension portion on one side thereof on which the channel formation region is present, and a junction depth of the extension portion is shallower than a junction depth of portions other than the extension portion.

In the semiconductor storage device of this one embodiment, variations in the width of the offset regions can be suppressed to a low one. As a result of this, variations in the memory effect can be suppressed to very low ones, and a semiconductor storage device of high reliability can be formed.

In one embodiment of the semiconductor storage device, a impurity concentration of the extension portion is lower than a impurity concentration of portions of the source/drain diffusion regions other than the extension portion.

In the semiconductor storage device of this one embodiment, the short-channel effect can be suppressed to more extent.

In one embodiment of the semiconductor storage device, the charge retention part of the memory function bodies is accommodated in the recesses.

In the semiconductor storage device of this one embodiment, since areas occupied by the charge retention part are limited to within the recesses, i.e., to small areas, erase of stored charge becomes easier to achieve, so that erase failures can be suppressed. Further, since the density of stored charge can be made higher only in the vicinities of the offset regions, the rewrite speed can be improved. Moreover, since the charge retention part is located at the lower portion of the gate electrode so that the gate electrode voltage has an effective influence, there can be provided a semiconductor storage device which is strong to the short-channel effect and high in rewrite speed.

In another aspect of the present invention, there is provided a semiconductor device comprising:

a memory area having a semiconductor storage element and a logic circuit area having a semiconductor switching element, both the memory area and the logic circuit area being provided on a semiconductor substrate, wherein

the semiconductor storage element and the semiconductor switching element are implemented, respectively, by field effect transistors each having a gate electrode and a pair of source/drain diffusion regions formed on portions of a semiconductor substrate surface corresponding to opposite sides of the gate electrode,

in either of the semiconductor storage element and the semiconductor switching element, recesses are formed so as to be increasingly widening sideways in cross section, respectively, and memory function bodies each of which is composed of a charge retention part made of a material having a function of storing electric charge and an anti-dissipation dielectric having a function of preventing dissipation of stored electric charge are formed on opposite sides of the gate electrode in such a fashion that the recesses are thereby buried,

the semiconductor storage element is so constituted as to be capable of, upon application of a voltage to the gate electrode, changing an amount of a current flowing from one of the source/drain diffusion regions to the other of the source/drain diffusion regions depending on a level of electric charge retained in the charge retention part, and

the semiconductor switching element is so constituted as to perform switching operation regardless of the level of electric charge retained in the charge retention part.

In the semiconductor storage device of this invention, a memory area having semiconductor storage elements and a logic circuit area having semiconductor switching elements are disposed on a semiconductor substrate. That is, semiconductor storage elements and semiconductor switching elements are compositely mounted within one identical substrate.

The composite mounting of flash memory and logic circuits in the prior art would involve the addition of seven to eight masks, compared with ordinary logic-circuit formation processes, from the reasons of the need for two polysilicon layers for a semiconductor storage element. However, in the semiconductor device of the present invention, unlike the above case, since the memory function bodies are formed not at regions for fulfilling the function of a gate insulator, but at opposite sides of the gate electrode, increases in the manufacturing processes in the composite mounting can be reduced to a large extent. That is, the semiconductor storage element has a structure similar to that of the semiconductor switching element, differing only in that the amount of a read current is changeable only in the semiconductor storage element, where considerable step increases such as would be seen in the prior art are not incurred due to the difference. Thus, it becomes implementable to reduce the manufacturing cost to a large extent, compared with the prior art.

In one embodiment of the semiconductor device, wherein, in the semiconductor switching elements, the source/drain diffusion regions are elongated and each of them is overlapped with the gate electrode end portion respectively, while in the semiconductor storage elements, spaces are provided between the bottom face of the gate electrode and the source/drain diffusion regions with respect to the gate length direction.

In the semiconductor device of this one embodiment, semiconductor switching elements in which the source region and the drain region are not offset from the gate electrode end, and semiconductor storage elements in which they are offset, are compositely mounted within an identical substrate. That is, in this semiconductor device, it becomes implementable to compositely mount within an identical substrate semiconductor switching elements in which the amount of a current flowing from one of the source/drain diffusion regions to the other of the source/drain diffusion regions is not substantially changed depending on a level of retained charge, and semiconductor storage elements in which the amount of the current can be so changed to a large extent. Further, since the semiconductor switching elements without the offset are large in drive current and the semiconductor storage elements with the offset are large in memory effect, logic circuits of a large drive current and memory of a large memory effect can easily be compositely mounted in this semiconductor device.

In one embodiment of the semiconductor device, a nonvolatile memory part is constituted of the semiconductor storage elements.

In the semiconductor device of this one embodiment, a logic circuit part having the semiconductor switching elements on an identical substrate and a nonvolatile memory part having the semiconductor storage elements can easily be compositely mounted.

In one embodiment of the semiconductor device, power supply voltages fed to the semiconductor storage elements of the memory area and the semiconductor switching elements of the logic circuit area are set independently each other.

In the semiconductor device of this one embodiment, for example, since a high power supply voltage can be fed to the semiconductor storage elements of the memory area, the write/erase speed can be greatly improved. Further, since a low power supply voltage can be fed to the semiconductor switching elements of the logic circuit area, deteriorations of transistor characteristics due to breakdown of the gate insulator or the like can be suppressed, allowing the power consumption to be further reduced. Thus, it becomes possible to implement a semiconductor device having a logic circuit part of high reliability and a memory part of remarkably fast write/erase speeds, both parts being easily compositely mounted on the same substrate.

In one embodiment of the semiconductor device, further, a static random access memory are constituted of the semiconductor switching elements.

In the semiconductor device of this one embodiment, since a logic circuit part and a static random access memory are constituted of the semiconductor switching elements and moreover a memory part is constituted of the semiconductor storage elements, it is easily achievable to compositely mount the logic circuit part as well as the static random access memory, and the nonvolatile memory part, on the same substrate. Furthermore, by the compositely mounting of the static random access memory as high-speed operation memory temporary storage memory, further functional improvement in the semiconductor device can be achieved.

According to the present invention, there is provided an IC card which is equipped with the semiconductor storage device or semiconductor device of the above-described invention.

In the IC card of this invention, the same working effects can be produced as the semiconductor storage device or semiconductor device of the above-described invention. For example, the IC card has a semiconductor device which allows memory and its peripheral circuit part, logic circuit part, SRAM part or the like to be easily compositely mounted so that a cost reduction has been achieved. Therefore, there can be provided an IC card which has been reduced in cost.

According to the present invention, there is provided portable electronic equipment which is equipped with the semiconductor storage device or semiconductor device of the above-described invention.

In the portable electronic equipment of this invention, the same working effects can be produced as the semiconductor storage device or semiconductor device of the above-described invention. For example, a portable telephone has a semiconductor device which allows memory and its peripheral circuit part, logic circuit part, SRAM part or the like to be easily compositely mounted so that a cost reduction has been achieved. Therefore, there can be provided a portable telephone which has been reduced in cost.

According to the present invention, there is provided a method for manufacturing a semiconductor storage device, comprising, in forming a semiconductor storage element constituted of a field effect transistor, the steps of:

forming a gate electrode on a semiconductor substrate surface via a gate insulator;

forming bird's beak dielectric films, which are increasingly widening sideways in cross section, between opposite side portions of the gate electrode and the semiconductor substrate surface, respectively;

removing the bird's beak dielectric films to thereby form recesses, which are increasingly widening sideways in cross section, at places from which the bird's beak dielectric films have been removed;

forming memory function bodies on opposite sides of the gate electrode in such a fashion that the recesses are thereby buried, each of the memory function bodies being composed of a charge retention part made of a material having a function of storing electric charge and an anti-dissipation dielectric having a function of preventing dissipation of stored electric charge; and

with the gate electrode and the memory function bodies used as a mask, implanting impurities to portions of the semiconductor substrate surface corresponding to opposite sides of the mask to thereby form a pair of source/drain diffusion regions.

In this semiconductor storage device manufacturing method, the semiconductor storage device of the above-described invention can be fabricated easily with simple process, and thus reduced in cost.

Further, since the lower portion of the gate electrode can be formed into such a configuration as to have recesses on opposite sides, injection and erase of electric charge are easy to achieve in terms of its structure. Thus, there can be provided a semiconductor storage device in which write/erase or read failures are suppressed and which is high in reliability.

Also, since the gate electrode voltage has an effective influence on the offset part of the channel, there can be provided a semiconductor storage device which is large in drive current in erasing so that misreads can be suppressed and which is fast in read speed.

Also, in the fabricated semiconductor storage device, the surface of the semiconductor substrate can be formed into a configuration having a flat portion which is opposed to a bottom face of the gate electrode via the gate insulator, slope portions which adjoin opposite sides of the flat portion with respect to a gate length direction to form part of the recesses, and bottom face portions each of which adjoins an outer side of the slope portion. In this case, the source/drain diffusion regions are formed at bottom-face portions of the semiconductor substrate surface, while the gate stack is formed at a flat portion of the semiconductor substrate surface, making it possible to form a configuration that those members are separate away from each other via the slope portion. Thus, since the substantial width of the offset regions is larger than the offset width of planar pattern design (in the lateral direction), a scale-down can be achieved on the design base while enough offset width is maintained. Also, the distance between a pair of source/drain diffusion regions is substantially larger than the distance on the planar pattern design. Therefore, deteriorations of transistor operations such as punch-through and short-channel effect due to the scale-down are suppressed. Thus, a semiconductor storage element which is suitable for scale-down can be formed and a semiconductor storage device which allows the manufacturing cost to be suppressed can be formed.

In one embodiment of the semiconductor storage device manufacturing method, the step of forming the memory function bodies include the steps of:

forming a first dielectric film which forms at least part of the anti-dissipation dielectric at a substantially uniform film thickness along the gate electrode and an exposed surface of the semiconductor substrate between which the recesses are formed;

forming silicon nitride as a material of the charge retention part on the exposed surface of the first dielectric film in such a manner that the recesses are thereby buried; and

etching the silicon nitride and the first dielectric film on opposite sides of the gate electrode so that the memory function bodies are left on opposite sides of the gate electrode, respectively.

In the semiconductor storage device manufacturing method of this one embodiment, the silicon nitride constituting the memory function bodies of the fabricated semiconductor storage device is isolated from the gate electrode and the semiconductor substrate by the first dielectric film. Therefore, dissipation of electric charge retained in the silicon nitride as a charge retention part into the gate electrode and the semiconductor substrate is suppressed, so that the retention characteristic is improved to a large extent. Further, since the memory function bodies can be formed in a self-alignment fashion, a semiconductor storage device of fewer masks and lower cost can be manufactured with very simple process.

In one embodiment of the semiconductor storage is device manufacturing method, the step of forming the memory function bodies include the steps of:

forming a first dielectric film which forms at least part of the anti-dissipation dielectric at a substantially uniform film thickness along the gate electrode and an exposed surface of the semiconductor substrate between which the recesses are formed;

forming silicon nitride film as a part of the charge retention part along the exposed surface of the first dielectric film;

forming second dielectric film as a part of the anti-dissipation dielectric at a substantially uniform film thickness along the exposed surface of the silicon nitride film; and

etching the silicon nitride and the first dielectric film on opposite sides of the gate electrode so that the memory function bodies are left on opposite sides of the gate electrode, respectively.

In the semiconductor storage device manufacturing method of this one embodiment, the silicon nitride constituting the memory function bodies of the fabricated semiconductor storage device is isolated from the gate electrode and the semiconductor substrate by the first dielectric film. Therefore, dissipation of electric charge retained in the silicon nitride as a charge retention part into the gate electrode and the semiconductor substrate is suppressed, so that the retention characteristic is improved to a large extent. Further, since the memory function bodies can be formed in a self-alignment fashion, a semiconductor storage device of fewer masks and lower cost can be manufactured with very simple process. Furthermore, since the silicon nitride is sandwiched between the first dielectric film and the second dielectric film, the dissipation of electric charge is suppressed to a large extent, so that a semiconductor storage device of improved retention characteristic can be manufactured.

In one embodiment of the semiconductor storage device manufacturing method, the step of etching the silicon nitride and the first dielectric film, portions of the silicon nitride other than the recesses are removed so that portions of the silicon nitride present in the recesses are left.

In the semiconductor storage device manufacturing method of this one embodiment, since areas occupied by the charge retention part are limited to within the recesses, i.e., to small areas, erase of stored charge becomes easier to achieve, so that erase failures can be suppressed. Further, since the density of stored charge can be made higher only in the vicinities of the offset regions, the rewrite speed can be improved. Moreover, since the charge retention part is located at the lower portion of the gate electrode so that the gate electrode voltage has an effective influence, there can be provided a semiconductor storage device which is strong to the short-channel effect and high in rewrite speed.

In one embodiment, the semiconductor storage device manufacturing method further comprises, after the step of forming the recesses and before the step of forming the memory function bodies, a step of introducing impurities with the gate electrode used as a mask to thereby form extension portions, a junction depth of which is shallower than a junction depth of the source/drain diffusion regions.

In the semiconductor storage device manufacturing method of this one embodiment, since the extension portions can be formed in a self-alignment fashion, a semiconductor storage device of fewer masks and lower cost can be manufactured with very simple process. Furthermore, variations in the width of the offset regions can be suppressed to a lower ones, so that the variations in the memory effect can be suppressed to very low ones, and a semiconductor storage device of high reliability can be formed.

Desirably, the extension portion is formed by performing impurity implantation at an implantation energy lower than that for the formation of the source/drain diffusion regions.

According to the present invention, there is provided a semiconductor device manufacturing method in which semiconductor storage elements each constituted of a field effect transistor are formed in a memory area set on a semiconductor substrate while semiconductor switching elements each constituted of a field effect transistor are formed in a logic circuit area set on the semiconductor substrate, the method comprising the steps of:

forming a gate electrode on portions of a semiconductor substrate surface corresponding to the memory area and the logic circuit area each via a gate insulator;

in both the memory area and the logic circuit area, forming bird's beak dielectric films, which are increasingly widening sideways in cross section, between opposite side portions of the gate electrode and the semiconductor substrate surface, respectively, and removing the bird's beak dielectric films to thereby form recesses, which are increasingly widening sideways in cross section, at places from which the bird's beak dielectric films have been removed;

introducing impurities into the logic circuit area with the gate electrode used as a mask while a mask is provided so that the impurities are not introduced into the memory area, thereby forming in the logic circuit a first doped region which forms part of source/drain diffusion regions;

in both the memory area and the logic circuit area, forming memory function bodies on opposite sides of the gate electrode in such a fashion that the recesses are thereby buried, each of the memory function bodies being composed of a charge retention part made of a material having a function of storing electric charge and an anti-dissipation dielectric having a function of preventing dissipation of stored electric charge; and

with the gate electrode and the memory function bodies used as a mask, implanting impurities, which are identical in conductive type to that of the preceding step, to each of the memory area and the logic circuit area to thereby form a second doped region which forms at least part of the source/drain diffusion regions.

In the semiconductor device manufacturing method of this invention, a semiconductor device in which semiconductor storage elements and semiconductor switching elements are compositely mounted can be fabricated by simple process with the addition of about one mask, allowing a cost reduction to be achieved. More specifically, semiconductor storage elements each constituted of a field effect transistor are formed in a memory area set on a semiconductor substrate while semiconductor switching elements each constituted of a field effect transistor are formed in a logic circuit area set on the semiconductor substrate. In the fabricated semiconductor storage elements and semiconductor switching elements, memory function bodies each of which is composed of a charge retention part made of a material having a function of storing electric charge, and an anti-dissipation dielectric having a function of preventing dissipation of stored electric charge, are formed on opposite sides of the gate electrode in such a fashion that the recesses between opposite side portions of the gate electrode and the semiconductor substrate surface are thereby buried. Also, in each of the fabricated semiconductor switching elements, in which the first doped region is disposed on the portions of the semiconductor substrate surface corresponding to opposite sides of the gate electrode, there is no spacing between the gate electrode and the source/drain diffusion regions with respect to the channel direction. On the other hand, in each of the fabricated semiconductor storage elements, a spacing (offset region) is provided between the gate electrode and the source/drain diffusion regions with respect to the channel direction, while memory function bodies each composed of a charge retention part made of a material having the function of storing electric charge and an anti-dissipation dielectric made of a material having the function of preventing the dissipation of stored electric charge are provided so as to cover the spacing on the semiconductor substrate surface. Further, since the semiconductor switching elements having no offset region are relatively large in drive current and the semiconductor storage elements having the offset region are relatively large in memory effect, it becomes easily achievable to compositely mount a logic circuit of large drive current and a nonvolatile memory of large memory effect.

### BRIEF DESCRIPTION OF THE DRAWINGS

The present invention will become more fully understood from the detailed description given hereinbelow and the accompanying drawings which are given by way of illustration only, and thus are not limitative of the present invention, and wherein:

FIGS. 1A-1D are schematic sectional views showing the structure of a semiconductor storage device according to a first embodiment of the present invention;

FIGS. 2A-2D are schematic sectional views showing the manufacturing process of a semiconductor storage device according to a second embodiment of the invention;

FIG. 3 is a schematic sectional view showing the structure of a semiconductor storage device according to the second embodiment of the invention;

FIGS. 4A-4C are schematic sectional views showing the manufacturing process of a semiconductor storage device according to a third embodiment of the invention;

FIGS. 5A-5C are schematic sectional views showing the manufacturing process of a semiconductor storage device according to a fourth embodiment of the invention;

FIGS. 6A-6D are schematic sectional views showing the manufacturing process of a semiconductor storage device according to a fifth embodiment of the invention;

FIG. 7 is a schematic sectional view showing the structure of a semiconductor storage device according to a sixth of the invention;

FIG. 8 is an enlarged view of a right-side memory function body 162 shown in FIG. 7 as well as a peripheral portion thereof;

FIG. 9 is a view showing an aspect that an end of silicon particles farther from the gate electrode out of a memory function body is not coincident with an end of a memory function body farther from the gate electrode in correspondence to FIG. 8;

FIG. 10 is a view showing an aspect that the charge retention part of the memory function body has a portion generally parallel to the surface of the gate insulator;

FIG. 11 is a view showing an aspect that the charge retention part of the memory function body is generally uniform in film thickness, disposed generally parallel to the surface of the gate insulator, and further disposed generally parallel to the gate electrode side face;

FIG. 12 is a view showing a gate electrode length A in a plane cut along the gate length direction, a distance (channel length) B between source/drain regions, and a distance C from an end of one memory function body to the other memory function body;

FIG. 13 is a schematic sectional view showing the structure of a semiconductor storage device according to a ninth embodiment of the invention;

FIG. 14 is a schematic sectional view showing the structure of a semiconductor storage device according to a tenth embodiment of the invention;

FIG. 15 is a schematic sectional view showing the structure of a semiconductor storage device according to an eleventh embodiment of the invention;

FIG. 16 is a schematic sectional view showing the structure of a semiconductor storage device according to a twelfth embodiment of the invention;

FIGS. 17A-17D are schematic sectional views showing the manufacturing process of a semiconductor device according to a thirteenth embodiment of the invention;

FIGS. 18A-18B are structural views of the semiconductor device according to the thirteenth embodiment of the invention, as well as its peripheral circuits, MPU, cache SRAM, and the like;

FIGS. 19A-19B are schematic block diagrams showing an IC card according to a fourteenth embodiment of the invention;

FIG. 20 is a schematic block diagram showing portable electronic equipment according to a fifteenth embodiment of the invention; and

FIG. 21 is a schematic sectional view outlining the structure of a conventional semiconductor storage device.

### DETAILED DESCRIPTION OF THE PREFERRED EMBODIMENTS

Hereinbelow, the present invention is described in detail with reference to the accompanying drawings. It is needless to say that the present invention is not limited to the following embodiments.

### First Embodiment

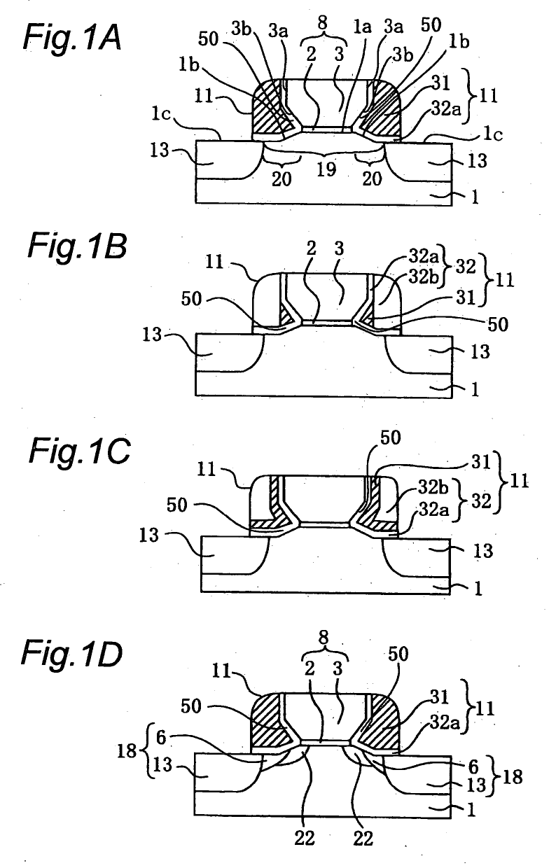

A semiconductor storage device of the first embodiment of the present invention is described with FIGS. 1A-1D.

The semiconductor storage device of this embodiment is, as shown in FIG. 1A, includes a FET having a gate electrode 3 formed on a semiconductor substrate 1 via a gate insulator 2, and a pair of source/drain diffusion regions 13, 13 formed on the semiconductor substrate surface corresponding to opposite sides of the gate electrode 3. A region between a pair of source/drain diffusion regions 13, 13 corresponds to a channel formation region 19. The gate insulator 2 and the gate electrode 3 constitute a gate stack 8.

Between opposite side portions of the gate electrode 3 and the semiconductor substrate surface are formed recesses 50, 50 which are increasingly widening sideways in cross section, respectively.

A side face of the gate electrode 3 has a flat portion 3a generally vertical to the surface of the gate insulator 2, and a slope portion 3b that adjoins the underside of this flat portion to form part of a recess 50.

The semiconductor substrate surface has a flat portion 1a opposed to the bottom face of the gate electrode 3 via the gate insulator 2, slope portions 1b, 1b which adjoin opposite sides of the flat portion with respect to the gate length direction, respectively, to form part of a recess 50, and bottom face portions 1c, 1c each of which adjoins an outer side of the slope portion 1b.

Memory function bodies 11, 11 are formed on opposite sides of the gate electrode 3 in such a fashion that the recesses 50, 50 are thereby buried. A memory function body 11 is composed of a charge retention part 31, which is made of a material having a function of storing electric charge, and an anti-dissipation dielectric (generically designated by reference numeral 32 for convenience) having a function of preventing dissipation of stored charge.

The anti-dissipation dielectric 32, in this example, is composed of a first dielectric 32a which is substantially uniform in film thickness and which covers the flat portions 3a and slope portions 3b of the side face of the gate electrode as well as the slope portions 1b and the bottom face portions 1c of the semiconductor substrate surface in such a manner that the charge retention part 31 and the gate electrode 3, as well as the charge retention part 31 and the semiconductor substrate 1, are thereby isolated from each other, respectively.

Spaces (offset regions) 20 are provided between the bottom face of the gate electrode 3 and the source/drain diffusion regions 13 with respect to the gate length direction. Each space 20 is covered with a memory function body 11.

That is, in this semiconductor storage device composed of FETs, a swelling portion is formed in the surface of the semiconductor substrate 1, and lower portions of side faces of the gate electrode 3 are inversely tapered. The channel formation region 19 is formed under the gate electrode 3, and a pair of source/drain diffusion regions 13, 13 having a conductive type reverse to that of the channel formation region are formed on opposite sides of the channel formation region 19. On side walls of the gate electrode 3 are formed memory function bodies 11, 11 each composed of a charge retention part 31, which is formed of silicon nitride having a function of storing electric charge, and an anti-dissipation dielectric 32, which has a function of preventing dissipation of stored electric charge.

Since the offset regions 20 are covered with the memory function bodies 11, respectively, the amount of a current that flows from one of the source/drain diffusion regions 13 to the other of the source/drain diffusion regions 13 upon application of a voltage to the gate electrode 3 can be changed depending on the amount of the charge retained by the memory function bodies 11, 11.

As shown in the figures, since the charge retention part is formed not at portions of the FET fulfilling the function of a gate insulator as shown in the prior art, but at portions beside the gate electrode, there can be solved the problem of overerase, which has been seen in the prior art.

Further, the source/drain diffusion regions 13, 13 are disposed at the bottom face portions 1c, 1c of the semiconductor substrate surface, while the gate stack 8 is positioned at the flat portion 1a of the semiconductor substrate surface, where those members are spaced from one another via the slope portions 1b. Accordingly, since the substantial offset width becomes larger than the design (lateral) offset width, the device can be scaled down while enough offset width is maintained. Also, the distance between the pair of source/drain diffusion regions 13, 13 becomes substantially larger than the design-base one from structural reasons, by which deteriorations of transistor operations such as punch-through and short-channel effect due to the scale-down are suppressed. Thus, there can be provided a semiconductor storage device which is suitable for scale-down and which allows the manufacturing cost to be suppressed.

Although the source/drain diffusion regions 13 are formed so as not to extend onto the slope portions 1b of the semiconductor substrate surface as shown in the figures, this is not limitative. That is, the source/drain diffusion regions 13 have only to be formed such that the source/drain diffusion regions 13, if formed so as to extend onto to the slopes, are still offset to the bottom face portion of the gate electrode 3 forming the gate stack 8 on the semiconductor substrate surface. Further, by so doing, the efficiency at which hot electrons that occur upon writing are injected into the memory function bodies can be enhanced. Also, with such a constitution, since the offset regions 20 can be formed so as to be covered with the gate electrode, the short-channel effect can be suppressed, allowing a scale-down to be achieved. Furthermore, in injection or ejection of electric charge by the voltage of the gate electrode 3, since the gate electrode 3 is located above the offset regions 20, the injection or ejection of electric charge can be achieved more efficiently. Therefore, the write speed can be improved.

Further, since the voltage of the gate electrode 3 effectively affects vicinities of the channel of the memory function bodies 11, 11 for structural reasons, electric charge is more easily injected and erased. Thus, there can be provided a semiconductor storage device in which write/erase or read failures are suppressed and which is high in reliability. Further, since the voltage of the gate electrode 3 effectively affects the offset part of the channel, there can be provided a semiconductor storage device which is so large in drive current in erasing operation that misreading can be suppressed and which is high in read speed.

Further, this semiconductor storage device, by virtue of the variable-resistance effect by the memory function bodies 11, is enabled to serve as a memory cell having functions both as a selective transistor and as a memory transistor.

Preferably, the semiconductor substrate 1 and the gate electrode 3 are formed with a material made of silicon. In this case, since the semiconductor substrate 1 and the gate electrode 3 are formed of silicon that nowadays is commonly used as a material of semiconductor devices, a semiconductor process highly compatible with conventional semiconductor manufacturing processes can be built up. Thus, a semiconductor storage device of low manufacturing cost can be provided.

Further, in an embodiment of the semiconductor storage device of the present invention, two- or more-bit information is stored in one element, by which the semiconductor storage device can be made to serve as a memory element that stores four- or more-value information.

The semiconductor storage device of the present invention may also have a construction as shown below.

Now designations of the memory function body and its individual portions are defined as follows.

It is assumed that a memory function body 11, as shown in FIGS. 1A to 1C, is composed of a charge retention part 31 which is formed beside the gate electrode 3 and which is made of a material which having a function storing electric charge, and an anti-dissipation dielectric 32, which has a function of preventing dissipation of stored electric charge. In this case, the anti-dissipation dielectric 32 may have a first dielectric 32a and a second dielectric 32b (FIGS. 1B, 1C), or have a first dielectric and no second dielectric (FIG. 1A).

The first dielectric 32a is so formed that the charge retention part 31 is isolated from the gate electrode 3 and the semiconductor substrate 1, while the second dielectric 32b is formed as a side wall spacer outside the charge retention part 31, both the first dielectric 32a and the second dielectric 32b having the function of preventing dissipation of stored electric charge. As a result, the charge retention characteristic is improved.

Also, as shown in FIGS. 1A-1D, the source/drain diffusion regions 13 are spaced from the gate electrode 3 in channel direction on the surface of the semiconductor substrate 1. More specifically, the gate stack 8, which is composed of the gate electrode 3 and the gate insulator 2, and the source/drain diffusion regions 13 are spaced from each other in the semiconductor substrate surface portions. That is, on the surface of the semiconductor substrate 1, the source/drain diffusion regions 13 are not present just under the bottom face of the gate electrode 3 (via the gate insulator 2), and are spaced to an extent of the width of the offset regions 20. In other words, the channel formation region 19 between the source region and the drain region is disposed under the memory function bodies 11 over the widths of the offset regions 20 in the surface of the semiconductor substrate 1. As a result, the injection of electrons as well as injection of holes into the memory function bodies are carried out efficiently, so that a semiconductor storage device of fast write and erase speeds can be formed.

Accordingly, in the semiconductor storage device, since the source/drain diffusion regions 13 are offset from the gate electrode 3, the degree of invertibility of the offset regions under the memory function bodies 11 with the voltage applied to the gate electrode 3 can be largely changed by the amount of charge stored in the memory function bodies 11, making it possible to increase the memory effect. Further, as compared with MOSFETs of common structure, the short-channel effect can be suppressed, making it possible to scale down the gate length. The structural suitability for the short-channel effect suppression from the above-mentioned reason makes it allowable to adopt a gate insulator film having a larger film thickness, as compared with that of logic transistors having no offset arrangement, thus making it possible to improve the reliability.

Further, the memory function bodies 11 of the semiconductor storage device are formed independently of the gate insulator 2. Therefore, the memory function served by the memory function bodies 11 and the transistor operation function served by the gate insulator 2 are separated from each other. Also, for the same reason, a material suitable for the memory function can be selected to form the memory function bodies 11.

In this case, as shown in FIG. 1C, the charge retention part 31 of the memory function bodies 11 is formed so as to be curved along the configuration of the gate electrode 3 or the semiconductor substrate 1. Although the charge retention part 31 is depicted with a curve in this figure, the curved portion is omitted in some of the figures after this on for simplicity's sake. Therefore, the configuration needs to be interpreted as appropriate in consideration of the individual embodiments.

Further, as shown in FIG. 1D, it is allowable that extension portions 6, 6 which are identical in conductive type to the source/drain diffusion regions and shallower in junction depth than the source/drain regions are formed inside a pair of source/drain diffusion regions 13, 13, i.e., in the offset regions. By the formation of source/drain regions including the extension portions 6 (generically designated by reference numeral 18), it becomes possible to form source/drain diffusion regions 18 that include extension portions so as to extend onto the slope portions 1b while the short-channel effect is suppressed. Accordingly, the injection efficiency of hot electrons into the memory function bodies is enhanced, so that writing can be efficiently achieved. Also, since upper portions of the offset regions can be formed so as to be covered with the gate electrode 3, the short-channel effect can be suppressed, allowing a scale-down to be achieved. Further, since the gate electrode 3 is located above the offset regions, the injection and ejection of electric charge with the voltage of the gate electrode 3 can be achieved more effectively, so that the write speed can be enhanced. In the case, if the extension portions 6 are more lightly doped than the other portions 13 of the source/drain diffusion regions 18, the short-channel effect can be suppressed to more extent, and conversely, if the extension portions 6 are more heavily doped, then the hot-carrier generation efficiency can be further enhanced.

Further, in the case where inside the source/drain diffusion regions 18 including the extension portions 6, counter regions 22 more heavily doped than the channel formation region located just under the bottom face of the gate electrode are formed at a conductive type reverse to that of the source/drain diffusion regions, the generation efficiency of hot electrons can be further enhanced, so that the write efficiency can be greatly enhanced.

Also, even when such counter regions are formed inside the source/drain diffusion regions 13, 13, i.e., in the offset regions of the semiconductor storage device described in FIGS. 1A-1C, the write efficiency is improved similarly.

Further, this semiconductor storage device may also be embodied in the following mode.

A semiconductor storage element that forms the memory of the semiconductor storage device of the present invention is composed mainly of a gate insulator, a gate electrode formed on the gate insulator, memory function bodies formed on opposite sides of the gate electrode of the semiconductor storage element, a channel formation region formed under the gate electrode, and source/drain diffusion regions which are formed on opposite sides of the channel formation region and which have a conductive type reverse to that of the channel formation region.

This semiconductor storage element stores two- or more-value information in one memory function body, thereby functioning as a semiconductor storage element that stores four- or more-value information. The semiconductor storage element, by virtue of its variable-resistance effect function of the memory function bodies, also serves as a memory cell having the functions of a selector transistor and a memory transistor at the same time. However, this semiconductor storage element does not necessarily need to be made to store four- or more-value information and function as such, but may be made to store two-value information function as well.

It is preferable that the semiconductor storage element constituting the semiconductor device of the present invention is formed on a semiconductor substrate, or in a well region formed in a semiconductor substrate and having the same conductivity type as the channel forming region in the semiconductor substrate.

The semiconductor substrate is not limited to particular ones as far as it is applicable to semiconductor apparatuses, and it is possible to use various substrates such as substrates made from elemental semiconductors including silicon and germanium, substrates made from compound semiconductors including SiGe, GaAs, InGaAs, ZnSe, and GaN, SOI (Silicon on Insulator) substrates and multilayer SOI substrates, and substrates having a semiconductor layer on a glass or plastic substrate. Among these, a silicon substrate or an SOI substrate having a silicon surface layer is preferable. The semiconductor substrate or the semiconductor layer may be either of a single crystal (e.g., single crystal obtained by epitaxial growth), polycrystalline, or amorphous, though a current amount flowing inside will be slightly different among them.

In the semiconductor substrate or the semiconductor layer, it is preferable that device isolation regions are formed, and it is more preferable to combine elements such as transistors, capacitors and resistors, a circuit composed thereof, a semiconductor device, and an inter-layer insulating film or films to form into a single or a multilayer structure. It is noted that the device isolation region may be formed by any of various device isolation films including a LOCOS (local oxidation of silicon) film, a trench oxide film, and an STI (Shallow Trench Isolation) film. The semiconductor substrate may be either of a P type or an N type conductivity type, and it is preferable that at least one first conductivity type (P type or N type) well region is formed in the semiconductor substrate. Acceptable impurity concentrations of the semiconductor substrate and the well region are those within the known range in the art. It is noted that in the case of using an SOI substrate as the semiconductor substrate, a well region may be formed in the surface semiconductor layer, and also a body region may be provided under the channel forming region.

Examples of the gate insulating film are not particularly limited and include those for use in typical semiconductor apparatuses, such as insulating films including silicon oxide films and silicon nitride films; and high-dielectric films including aluminum oxide films, titanium oxide films, tantalum oxide films, hafnium oxide films, in the form of single-layer films or multi-layer films. Among these, the silicon oxide film is preferable. An appropriate thickness of the gate insulating film is, for example, approx. 1 to 20 nm in equivalent insulator thickness, preferably 1 to 6 nm. The gate insulating film may be only formed right under the gate electrode, or may be formed to be larger (in width) than the gate electrode.

The gate electrode or electrode is formed on the gate insulation film normally in a shape for use in a semiconductor device or a shape that has a concave portion in a lower end portion. Herein, the “single gate electrode” is defined as a gate electrode consisting of a monolayer or multilayer conductive film and formed into a single inseparable piece. The gate electrode may have a side wall insulation film on each side surface. The gate electrode is normally not specifically limited so long as it is used for a semiconductor device, and there can be enumerated conductive films of: polysilicon; metals including copper and aluminum; high-melting metals including tungsten, titanium, and tantalum; and silicides of high-melting metals, in the form of a single-layer or a multi-layer. The gate electrode should properly be formed with a film thickness of, for example, about 50 to 400 nm. It is to be noted that a channel forming region is formed under the gate electrode.

The memory function body has at least a film or a region having a function of retaining electric charges, a function of storing and retaining charges, a function of trapping charges or a function of retaining a charge polarized state. Materials implementing these functions include: silicon nitride; silicon; silicate glass including impurities such as phosphorus or boron; silicon carbide; alumina; high-dielectric substances such as hafnium oxide, zirconium oxide, or tantalum oxide; zinc oxide; and metals. The memory function body may be formed into single-layer or multi-layer structure of: for example, an insulating film containing a silicon nitride film; an insulating film incorporating a conductive film or a semiconductor layer inside; and an insulating film containing one or more conductor dots or semiconductor dots. Among these, the silicon nitride is preferable because it can achieve a large hysteresis property by the presence of a number of levels for trapping electric charges, and has good holding characteristics in that the electric-charge holding time is long and that there hardly occurs leakage of electric charges caused by generation of leakage paths, and further because it is a material normally used in LSI process.

Use of an insulating film containing inside an insulating film having a charge holding function such as a silicon nitride film enables increase of reliability relating to memory holding. Since the silicon nitride film is an insulator, electric charges of the entire silicon nitride film will not be immediately lost even if part of the electric charges is leaked. Further, in the case of arraying a plurality of storage devices, even if the distance between the storage devices is shortened and adjacent memory function bodies come into contact with each other, information stored in each memory function body is not lost unlike the case where the memory function body is made from a conductor. Also, it becomes possible to dispose a contact plug closer to the memory function body, or in some cases it becomes possible to dispose the contact plug so as to overlap with the memory function body, which facilitates miniaturization of the storage devices.

For further increase of the reliability relating to the memory holding, the insulator having a function of holding electric charges is not necessarily needed to be in the film shape, and insulators having the function of holding an electric charge are preferably present in an insulating film in a discrete manner. More specifically, it is preferable that an insulator is dispersed like dots over a material having difficulty in holding electric charges, such as silicon oxide.

Also, use of an insulator film containing inside a conductive film or a semiconductor layer as a memory function body enables free control of quantity of electric charges injected into the conductor or the semiconductor, thereby bringing about an effect of facilitating achieving multi level cell.

Further, using an insulator film containing one or more conductor or semiconductor dots as a memory function body facilitates execution of write and erase due to direct tunneling of electric charges, thereby bringing about an effect of reduced power consumption.

Moreover, it is acceptable to use, as a memory function body, a ferroelectric film such as PZT (lead zirconate titanate) and PLZT (lead lanthanum zirconate titanate) whose polarization direction is changed by an electric field. In this case, electric charges are substantially generated by polarization on the surface of the ferroelectric film and retained in the state. Therefore, electric charges are supplied from outside the film that has the memory function, and a hysteresis characteristic similar to that of the film that traps electric charges can be obtained. In addition, since there is no need to inject electric charges from outside the film and the hysteresis characteristic can be obtained only by the polarization of the electric charges in the film, high-speed write and erase is achievable.

It is preferable that the memory function body further contains a region that obstructs escape of electric charges or a film having a function of obstructing escape of electric charges. Materials fulfilling the function of obstructing escape of electric charges include a silicon oxide.

The charge holding portion contained in the memory function body is formed on opposite sides of the gate electrode directly or through an insulating film, and it is disposed on the semiconductor substrate (a well region, a body region, or a source/drain diffusion region or a diffusion layer region) directly or through the gate insulating film or the insulating film. The charge holding portions on opposite sides of the gate electrode are preferably formed so as to cover all or part of side walls of the gate electrode directly or thought the insulating film. In an application where the gate electrode has a recess portion on the lower edge side, the charge holding portion may be formed so as to fill the entire recess portion or part of the recess portion directly or through the insulating film.

Preferably, the gate electrode is formed only on the side wall of the memory function body or formed such that the upper portion of the memory function body is not covered. In such disposition, it becomes possible to dispose a contact plug closer to the gate electrode, which facilitates miniaturization of the semiconductor storage elements. Also, the semiconductor storage elements having such simple disposition are easily manufactured, resulting in an increased yield.

In the case of using a conductive film as the charge holding portion, the charge holding portion is preferably disposed with interposition of an insulating film so that the charge holding film is not brought into direct contact with a semiconductor substrate (a well region, a body region, or a source/drain diffusion region or a diffusion layer region) or the gate electrode. This is implemented by, for example, a multi-layer structure composed of a conductive film and an insulating film, a structure of dispersing a conductive film like dots in an insulating film, and a structure of disposing a conductive film within part of a side-wall insulating film formed on the side wall of the gate.

The source/drain diffusion regions are disposed on the side of the memory function bodies opposed from the gate electrode as diffusion regions having a conductivity type opposite to that of the semiconductor substrate or of the well region. In the portion where the source/drain diffusion region is joined to the semiconductor substrate or the well region, impurity concentration is preferably sharp. This is because the sharp impurity concentration efficiently generate hot electrons and hot holes with low voltages, which enables high-speed operations with lower voltages. The junction depth of the source/drain diffusion region is not particularly limited and so it is adjustable where necessary, according to performance and the like of a memory device to be manufactured. It is noted that if an SOI substrate is used as the semiconductor substrate, the junction depth of the source/drain diffusion region may be smaller than the film thickness of a surface semiconductor layer, though preferably the junction depth is almost equal to the film thickness of the surface semiconductor layer.

The source/drain diffusion region may be disposed so as to be overlapped with the edge of the gate electrode, or to meet the edge of the gate electrode, or to be offset from the edge of the gate electrode. Particularly, it is preferable that the source/drain diffusion region is offset relative to the edge of the gate electrode. This is because in this case, when voltage is applied to the gate electrode, easiness of inversion of the offset region under the charge holding portion is largely changed by an electric charge amount stored in the memory function body, resulting in increased memory effect and reduced short channel effect. It is noted, however, that too much offset extremely reduces drive current between the source and the drain. Therefore, it is preferable that an offset amount, that is a distance from one edge of the gate electrode to the source or drain region closer thereto in the gate length direction, is shorter than the thickness of the charge holding portion in the gate length direction. What is particularly important is that at least part of the charge holding portion in the memory function body overlaps with the source/drain diffusion region serving as a diffusion layer region. This is because the nature of semiconductor storage elements constituting the semiconductor device of the present invention is to rewrite memory with an electric field crossing the memory function body by voltage difference between the gate electrode present only on the side wall portion of the memory function body and the source/drain diffusion region.

Part of the source/drain diffusion region may be extended to the position higher than the surface of the channel forming region, that is, the lower face of the gate insulating film. In this case, it is appropriate that a conductive film is laid on a source/drain diffusion region formed in the semiconductor substrate in an integrated manner with the source/drain diffusion region. Examples of the conductive film include semiconductors such as polysilicon and amorphous silicon, silicide, and the above described metals and high-melting metals. Among these, the polysilicon is preferable. Since the polysilicon is extremely larger in impurity diffusion speed than the semiconductor substrate, it is easy to shallow the junction depth of the source/drain diffusion region in the semiconductor substrate, and it is easy to control short channel effect. In this case, it is preferable that the source/drain diffusion region is disposed such that at least part of the charge holding film is sandwiched between part of the source/drain diffusion region and the gate electrode.

The semiconductor storage element of the present invention can be formed by the ordinary semiconductor process according to a method similar to the method of forming a side wall spacer of a single layer or laminate structure on the side wall of the gate electrode or word line. In concrete, there can be enumerated: a method comprising forming a gate electrode or a word line, thereafter forming a single layer film or multilayer film including a charge retaining portion, such as a charge retaining portion, a charge retaining portion/insulation film, an insulation film/charge retaining portion, and an insulation film/charge retaining portion/insulation film, and leaving the film or films in a side wall spacer shape by etching back under appropriate conditions; a method comprising forming an insulation film or a charge retaining portion, leaving the film in a side wall spacer shape by etching back under appropriate conditions, further forming a charge retaining portion or insulation film and leaving the film in a side wall spacer shape by etching back under appropriate conditions; a method comprising coating or depositing, on a semiconductor wafer including a gate electrode, an insulation film material in which a particulate charge retaining material is distributed, and leaving the insulation film material in a side wall spacer shape by etching back under appropriate conditions; a method comprising forming a gate electrode, thereafter forming the single layer film or the multilayer film and carrying out patterning by using a mask, and so on. Moreover, there can be enumerated a method comprising forming a charge retaining portion, a charge retaining portion/insulation film, an insulation film/charge retaining portion, or an insulation film/charge retaining portion/insulation film before forming a gate electrode or an electrode, forming an opening through the film or films in a region that becomes a channel forming region, forming a gate electrode material film on the entire upper surface of the wafer and patterning this gate electrode material film in a shape, which is larger than the opening in size and encompasses the opening.

When a memory cell array is constructed by arranging the semiconductor storage elements of the present invention, a best mode of the semiconductor storage elements is to satisfy, for example, the following required conditions:

(i) The function of a word line is possessed by the integrated body of the gate electrodes of a plurality of semiconductor storage elements;

(ii) The memory function body is formed on each of opposite sides of the word line;

(iii) A material that retains electric charges in the memory function body is an insulator, and in particular, a silicon nitride film;

(iv) The memory function bodies are constructed of an ONO (Oxide Nitride Oxide) film, and the silicon nitride film has a surface roughly parallel to the surface of the gate insulation film;

(v) The silicon nitride film in each memory function body is separated from the word line and the channel forming region by the silicon oxide film;

(vi) A silicon nitride film in each memory function body overlaps with the corresponding diffusion region;

(vii) The thickness of the insulation film, which separates the silicon nitride film that has a surface roughly parallel to the surface of the gate insulation film from the channel forming region or the semiconductor layer differs from the thickness of the gate insulation film;

(viii) Write and erase operations of one semiconductor storage element are executed by a single word line;

(ix) There is no electrode (word line), on each memory function body, which has a function to assist the write and erase operations; and

(x) A portion put in contact with the diffusion region right under each memory function body has a region where the impurity concentration of the conductivity type opposite to the conductivity type of the diffusion region is high.

The best mode is a mode in which all of these requirements are satisfied, but it is not necessary to satisfy all requirements.

When some of the above requirements are satisfied, there are most preferable combinations of requirements. For example, a most preferable combination resides in that (iii) a material that retains electric charges in the memory function body is an insulator, and in particular, a silicon nitride film; (ix) there is no electrode (word line), on each memory function body, which has a function to assist the write and erase operations; and (vi) an insulator (silicon nitride film) in each memory function body overlaps with the corresponding diffusion region. According to the finding by the inventors, when an insulator retains electric charges in the memory function body and there is no electrode, on each memory function body, which has a function to assist the write and erase operations, write operations are well performed only if the insulator (silicon nitride film) in each memory function body overlaps with the corresponding diffusion region. That is, when requirements (iii) and (ix) are satisfied, it is particularly preferred that requirement (vi) be satisfied. On the other hand, if a conductor retains electric charges in the memory function body or if there is an electrode, on each memory function body, which has a function to assist the write and erase operations, the write operations are effected even if the insulator in each memory function body does not overlap with the corresponding diffusion region. However, if an insulator retains electric charges in the memory function body or if there is no electrode, on each memory function body, which has a function to assist the write and erase operations, the following great advantages are obtained. That is, it is possible to place a contact plug closer to the memory function body. Or, even if the semiconductor storage elements are put close to each other in distance, the plurality of memory function bodies do not interfere with one another, and the storage information can be retained. Therefore, the miniaturization of the semiconductor storage elements is facilitated. Furthermore, since the element structure is simple, the number of fabrication process steps is reduced, and the yield can be improved. Also, combination with the transistors that constitute a logic circuit and an analog circuit can be facilitated. Furthermore, we have ascertained that the write and erase operations can be executed at a low voltage of not higher than 5 V. This is why satisfying requirements (iii), (ix) and (vi) is particularly preferable.

The semiconductor device of the present invention in which semiconductor storage elements are combined with logic elements is applicable to battery-driven portable electronic equipment, in particular mobile information terminals. Examples of the portable electronic equipment are mobile phones and game machines, in addition to mobile information terminals.

The first embodiment describes the N-channel devices. However, the devices may be of P channel, in which case the conductivity types of the impurities should be reversed.

Moreover, in the drawings, the same reference numerals are given to the portions where the same material and substances are used and do not necessarily indicate the same shapes.

Moreover, it is to be noted that the drawings are schematic, and the dimensional relations between thickness and plane, ratios of thickness and size between layers and portions and so on are different from those of the actual ones. Therefore, the concrete dimensions of thickness and size should be determined in consideration of the following description. Moreover, there are, of course, included the portions whose mutual dimensional relations and ratios are different between the figures.

Moreover, the thickness and the size of the layers and portions described in the present patent specification are the dimensions of the final shapes in the stage in which the formation of the semiconductor device is completed unless specifically described. Therefore, it is to be noted that the dimensions of the final shapes somewhat change depending on the thermal history and so on of the subsequent processes in comparison with the dimensions immediately after the formation of the films, the impurity regions and so on.

### Second Embodiment

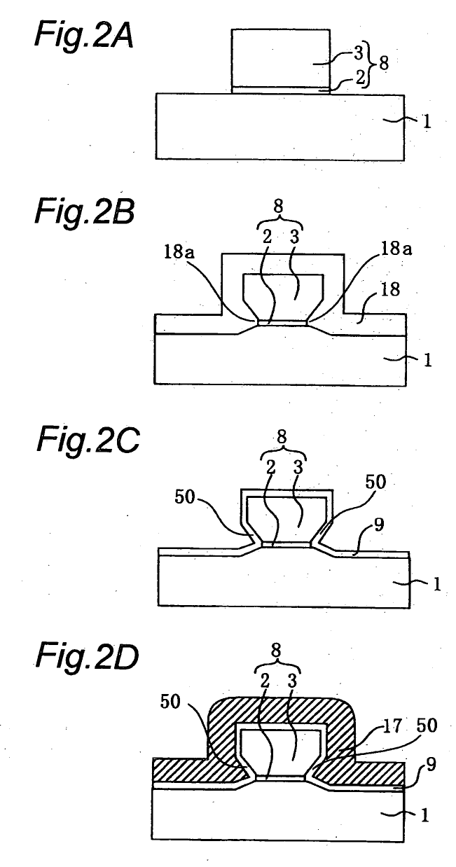

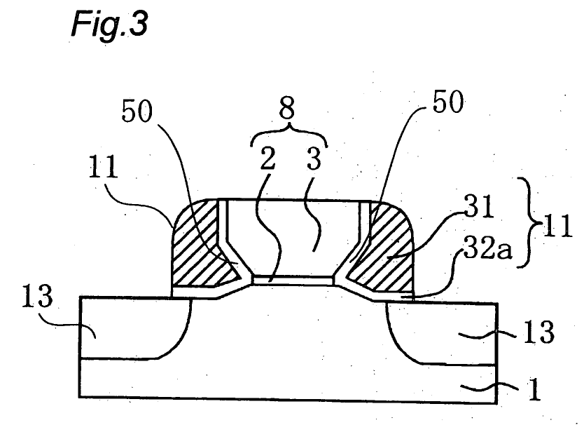

A semiconductor storage device of a second embodiment of the invention is explained with reference to FIGS. 2A-2D and FIG. 3.

Its manufacturing process is described below in sequence along FIGS. 2A-2D.

As shown in FIG. 2A, a gate insulator 2 and a gate electrode 3, i.e. a gate stack 8, which have the MOS structure and which have been subjected to the MOS (Metal-Oxide-Semiconductor) formation process are formed on a silicon substrate 1 having the P conductive type.

A typical MOS formation process is as follows.

First, as required, a device isolation region is formed by a known method on the semiconductor substrate 1 made of silicon and having a p-type semiconductor region. The device isolation region can prevent a leakage current from flowing through the substrate between mutually adjacent devices. However, even mutually adjacent devices, if associated with the source/drain diffusion region 13 in common, do not need the formation of such a device isolation region. Forming the device isolation region makes it possible to prevent leakage currents from flowing between neighboring devices through the substrate. It is noted that such a device isolation region does not need to be formed for those neighboring devices between which the source/drain diffusion regions are shared. The aforementioned known device-isolation-region formation method has only to be one that allows the objective of isolating devices from each other to be achieved, whichever the method is the known one using LOCOS oxide, or the known one using trench isolation regions, or other known methods. In this embodiment, which is described on a case where the device isolation region is not formed, the device isolation region is not shown in the figures.

Next, although not shown in particular, an impurity diffusion region is formed on and around an exposed surface of the semiconductor substrate. This impurity diffusion region is intended for control of the threshold voltage, and for increase of the impurity concentration of the channel formation region. An appropriate impurity diffusion region may be formed by a known method for obtaining an appropriate threshold voltage.

Next, a dielectric film is formed entirely on the exposed surface of the semiconductor region. This dielectric film, which has only to be able to suppress the leakage, may be formed as an oxide film, a nitride film, a composite film of an oxide film and a nitride film, a high-dielectric film of hafnium oxide, zirconium oxide or the like, or a composite film of a high-dielectric film and an oxide film. Further, since the film forms the gate insulator of a MOSFET, it is desired that a film having good performance as the gate insulator is formed by using a process including N₂O oxidation, NO oxidation, after-oxidation nitriding, and other steps. The film having good performance as the gate insulator means a dielectric film capable of suppressing every disadvantageous factor in advancing scale-down and performance enhancement of MOSFETs, for example, suppressing the MOSFET short-channel effect, suppressing leakage currents that are currents unnecessarily flowing through the gate insulator, and suppressing diffusion of impurities of the gate electrode into the MOSFET channel formation region while suppressing depletion of impurities of the gate electrode. Typically, the film is an oxide film such as thermal oxide film, N₂O oxide film or NO oxide film, its film thickness being appropriately within a range of 1 nm to 6 nm.

Next, a gate electrode material is formed on the dielectric film. As the gate electrode material, any material may be used only if it is capable of exhibiting the performance as MOSFET, such as polysilicon, doped polysilicon or other semiconductors, Al, Ti, W or other metals, compounds of these metals and silicon. When polysilicon film is formed in this case as an example, the polysilicon film thickness is preferably 50 nm to 400 nm.

Next, a desired photoresist pattern is formed on the gate electrode material by photolithography process, and with the resulting photoresist pattern used as a mask, gate etching is performed so that the gate electrode material and the gate insulator are etched so as to form a structure of FIG. 2A. That is, the gate insulator 2 and the gate electrode 3, and the gate stack 8 constituted of those is formed. Although not shown, in this process, it is allowable that the gate insulator is not etched. When the gate insulator, without being etched, is utilized as an implantation protective film in the subsequent-step impurity implantation, the step of forming an implantation protective film can be simplified.

It is noted that materials of the gate insulator 2 and the gate electrode 3 may be ones which are used in logic processes complying with the days' scaling law, and are not limited to the aforementioned ones.

Further, the gate stack 8 may also be formed by the following process. A gate insulator constituted as described above is formed entirely on the exposed surface of the semiconductor substrate 1 having a p-type semiconductor region. Next, a gate electrode material constituted as described above is formed on the gate insulator. Next, a mask dielectric film of oxide, nitride, oxynitride or the like is formed on the gate electrode material. Next, a photoresist pattern constituted as described above is formed on the mask dielectric film, and then the mask dielectric film is etched. Next, the photoresist pattern is removed, and with the mask dielectric film used as an etching mask, the gate electrode material is etched. Next, the mask dielectric film and the exposed portion of the gate insulator are etched, by which the structure of FIG. 2A is formed. In the case where the gate stack is formed in this way, the selection ratio in etching, i.e., the selection ratio of gate electrode material to gate insulator material can be made larger so that the etching of a thin-film gate insulator becomes achievable without etching the substrate. In this case, although not shown, the gate insulator does not need to be etched for the same reason as described above.

Next, as shown in FIG. 2B, thermal oxidation is performed, by which a bird's beak dielectric film 18 which is made of silicon oxide and which has portions 18a, 18a increasingly widening sideways in cross section are formed between opposite side portions of the gate electrode 3 and the semiconductor substrate 1 surface, respectively. Such a bird's beak (portions 18a, 18a increasingly widening in cross section) can be formed by performing oxidation so thick that an oxide film is formed so as to intrude into the interface between the gate electrode 3 and the semiconductor substrate 1. Whereas a thick film of oxide needs to be formed in this case, the formation of the bird's beak is enabled even with a thin oxidation if the oxidation is performed under the following conditions. That is, the oxidation should be done under such a condition that the reactive species (oxygen for oxidation) is well diffused into the interface between the gate electrode and the semiconductor substrate, i.e., under a higher pressure or higher temperature or under a higher pressure or higher temperature as well as a lower partial pressure of the reactive species than in normal oxidation conditions. Although a film of oxide is used as the bird's beak dielectric film 18, yet a film of nitride is also usable, and further a mixed film of nitride and oxide is substitutable. By this step, a swelling portion can be formed on the surface of the semiconductor substrate 1, and further lower portions of the side faces of the gate electrode 3 can be formed inversely tapered.

Next, as shown in FIG. 2C, the bird's beak dielectric film 18 is removed, by which recesses 50, 50 increasingly widening sideways in cross section are formed at the places from which the bird's beak dielectric film 18 has been removed, i.e., at places between opposite side portions of the gate electrode 3 and the semiconductor substrate 1 surface. Subsequently, a first dielectric film 9 made of oxide is formed generally uniformly along the gate stack 8, where the recesses 50, 50 have been formed, and the exposed surfaces of the semiconductor substrate 1. This first dielectric film 9 forms part of an anti-dissipation dielectric (which would be described later). This first dielectric film 9, for which oxide is used in this case, is preferably given by a film having a high withstand voltage, small leakage current and high reliability since it becomes a dielectric film through which electrons are passed. For example, an oxide film such as a thermal oxide film, an N₂O oxide film, an NO oxide film and the like is used as with the material of the gate insulator 2. Its film thickness of oxide is preferably 1 nm to 20 nm. Further, when this dielectric film is formed so thin that a tunneling current flows, the voltage required for injection or erase of electric charge can be made lower, thus allowing the power consumption to be reduced. A typical film thickness for that case is preferably 3 nm to 8 nm.

In this process, after the bird's beak dielectric film is once formed, the dielectric film is removed and again a dielectric film thinner than that is formed. However, such a process as shown below other than this process may also be adopted. That is, in the gate electrode formation process described in FIG. 2A, etching process is performed in such a way that lower portions of the side faces of the gate electrode become inversely tapered. In this step, an etching of up to a vicinity of the gate oxide surface is done under such conditions that deposits are provided on the side faces of the gate electrode. Those deposits are thicker in upper portions increasingly upward. Next, an etching for completely removing the oxide is performed, in which process the lower portions of the side faces of the gate electrode where the deposits are either thin or not provided are etched at the same time. As a result, a structure that recesses are provided at the lower portions of opposite side faces of the gate electrode is formed. Then, a bird's beak oxide film made of oxide is formed by performing ordinary oxidation or under such conditions that a thinner oxide film is formed as described in the explanation of FIG. 2B. As a result of this, a structure similar to that shown in FIG. 2C, or a structure in which the semiconductor substrate is flat and which is similar thereto only in gate electrode can be formed. Even with the semiconductor substrate flat, the same steps as in the case where the semiconductor substrate is not flat can be used for the following steps. In the case where the semiconductor substrate is flat, working effects that can be produced with the non-flat semiconductor substrate cannot be produced, as compared with the case where the semiconductor substrate is not flat, but a working effect that the drive current is increased can be produced.

Next, as shown in FIG. 2D, silicon nitride 17 is deposited generally uniformly as the material of the charge retention parts in such a fashion that the recesses 50 are thereby buried. The semiconductor storage device of the silicon nitride 17 has only to be 2 nm to 100 nm, for example. This film thickness, which is an important parameter for the source/drain diffusion regions to be formed with an offset from the gate electrode 3, may be controlled within the film thickness range in consideration of offset amount. Although silicon nitride is used in this case, it is also possible to use, instead of silicon nitride, materials capable of retaining or inducing electric charge, for example, such a material as an oxynitride capable of retaining a substance having charge of electrons and holes and the like or an oxide having charge traps, or such a material as a ferroelectric capable of inducing electric charge to the surfaces of memory function bodies by polarization or other phenomena, or such a material as those having a structure that a floating substance like polysilicon or silicon dots capable of retaining electric charge is possessed in an oxide film. Also when these materials are used, the same working effects as with the use of silicon nitride are produced.

In this case, by the formation of the first dielectric film 9, the silicon nitride 17 having the function of storing electric charge is in contact with the semiconductor substrate and the gate electrode via the dielectric film, so that leakage of the retained charge can be suppressed by this dielectric film. Thus, a semiconductor storage device good at charge retention characteristic and high in long-term reliability can be realized.

Next, as shown in FIG. 3, the silicon nitride 17 is etched and the first dielectric film 9 is etched, by which memory function bodies 11, 11 each composed of a first dielectric 32a and a charge retention part 31 are formed as side walls on opposite side faces of the gate stack 8. The first dielectric 32a is formed of part of the first dielectric film 9, and the charge retention part 31 is made of part of the silicon nitride.

Further, with the gate electrode 3 and the memory function bodies 11, 11 used as a mask, impurity implantation for forming conventional source/drain diffusion regions 13 is performed, and then desired thermal treatment is performed, by which the source/drain diffusion regions 13 are formed. In this case, the source/drain diffusion regions 13 may also be formed before the formation of the memory function bodies 11, or after the formation of the memory function bodies 11, where the same effects are produced in principle in either case. However, when the source/drain diffusion regions 13 are formed before the formation of the memory function bodies 11 are formed, there is no need for the implantation protective film, allowing a process simplification to be achieved. Here has been described a case where the source/drain diffusion regions 13 are formed after the formation of the memory function bodies 11.

Now the process for forming the above-described memory function bodies is explained in detail below.

First, the silicon nitride 17 is anisotropically etched, by which the silicon nitride 17 is left as side walls on the side walls of the gate stack 8 via the first dielectric film 9. In this case, the etching is preferably performed under such conditions that the first dielectric film 9 can be selectively etched and that the etching selection ratio to the first dielectric film 9 made of oxide is a large one.

Next, the first dielectric film 9 is anisotropically etched, by which first dielectrics 32a made of part of the first dielectric film 9 are formed on the side walls of the gate stack 8. In this case, the etching is preferably performed under such conditions that the first dielectric film 9 can be selectively etched and that the etching selection ratio to the silicon nitride 17, the gate electrode 3 and the semiconductor substrate 1 is a large one.

In this way, on opposite sides of the gate stack 8, the memory function bodies 11, 11 are formed as side walls in such a fashion that the recesses 50 are thereby buried.

Next, source/drain diffusion regions 13 are formed. That is, with the gate electrode 3 and the memory function bodies 11, 11 used as a mask, impurities having a conductive type reverse to that of the channel formation region are implanted, and thermal treatment for conventional activation is performed. As a result, source/drain diffusion regions 13, 13 having a specified junction depth are formed in a self-alignment fashion. In this case, since impurity implantation into the semiconductor substrate 1 is performed not through a coating film, it is appropriate that with the injection energy controlled, impurities are implanted shallow by the extent of the film thickness of the coating film, which is absent, so that the junction is formed to a specified depth.

Now through the above steps, memory function bodies have been formed. A semiconductor storage device employing these memory function bodies has the following working effects.

When electric charge is retained in the charge retention parts 31 of the memory function bodies 11, part of the channel formation region is strongly affected by electric charge, causing the drain current value to be changed. Thus, a semiconductor storage device that distinguishes the presence or absence of electric charge depending on the change of the drain current value is formed.

Also, the gate insulator 2 and the memory function bodies 11, because of their being disposed separate from each other, can be subjected to different types of scaling. Thus, a semiconductor storage device which suppresses the short-channel effect to be good at memory effect can be provided.

Also, since the silicon nitride 17 in the memory function bodies is in contact with the semiconductor substrate 1 and the gate electrode 3 via the dielectric film, leakage of the retained charge can be suppressed by this dielectric film. As a result of this, a semiconductor storage device which is good at charge retention characteristic and high in long-term reliability is formed.

Also, in the case where an electrical conductor or semiconductor is used as the memory function bodies, when a positive voltage is applied to the gate electrode, there occurs polarization within the memory function bodies, causing electrons to be induced to vicinities of the gate electrode side wall portions so that the electrons in the vicinities of the channel formation region are decreased. As a result of this, injection of electrons from the substrate or the source/drain diffusion regions can be accelerated, so that a semiconductor storage device fast in write speed and high in reliability can be formed.

### Third Embodiment

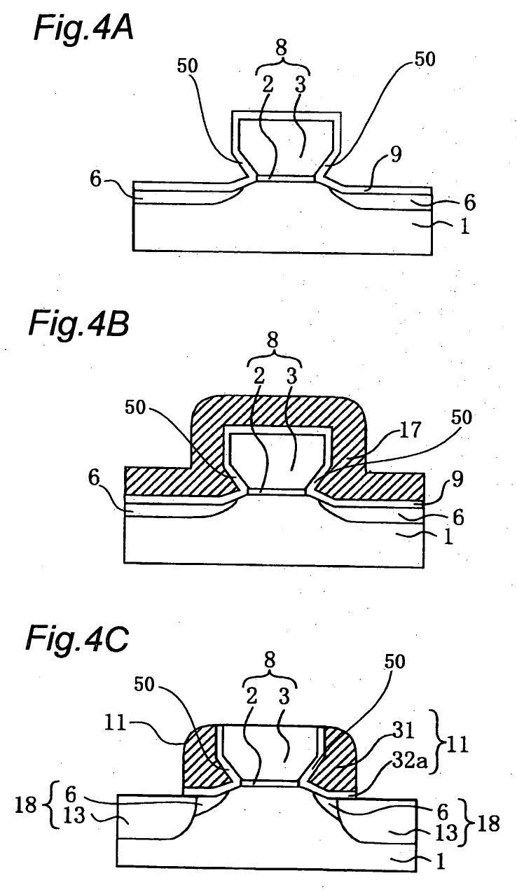

A semiconductor storage device of a third embodiment of the invention is explained in detail with reference to FIGS. 4A-4C.

The semiconductor storage element in this embodiment is, as shown in FIG. 4C, generally similar in construction to the semiconductor storage element of the second embodiment. However, this embodiment is characterized in that such extension portions 6 and/or counter regions 22 as shown in FIG. 1D are provided. By this embodiment, it is enabled to form the above-described structure in self alignment without increasing any special mask. Further, extension portions 6 shallower in junction depth than the source/drain diffusion regions 13 are formed inside a pair of source/drain diffusion regions 13, 13, i.e. in the offset regions, with a conductive type identical to that of the source/drain diffusion regions, by which source/drain diffusion regions 18 including the extension portions are formed. As a result of this, source/drain diffusion regions 18 which include extension portions so as to adjoin the slopes with the short-channel effect suppressed can be formed, so that the injection efficiency of hot electrons into the memory function bodies is increased, allowing the writing to be efficiently performed. Also, since upper portions of the offset regions can be formed so as to be covered with the gate electrode 3, the short-channel effect can be suppressed and a further scale-down becomes implementable. Further, since is the gate electrode is placed above the offset regions, injection and ejection of electric charge by the voltage of the gate electrode 3 can be performed more efficiently, so that the write speed can be improved. In this case, making the impurity concentration of the extension portions 6 lower than the other portions 13 in the source/drain diffusion regions 18 allows the short-channel effect to be suppressed to more extent and, conversely, making the same impurity concentration higher allows the generation efficiency of hot carriers to be increased.

Further, when counter regions 22 which are reverse in conductive type to the source/drain diffusion regions and which are higher in impurity concentration than the channel formation region are formed inside the source/drain diffusion regions 18 including the extension portions, the generation efficiency of hot electrons can further be increased and the write efficiency can be greatly increased.

Even when these counter regions 22 are formed inside the source/drain diffusion regions 13, i.e., in the offset regions, the write efficiency is improved likewise.

Further, since the extension portions 6 are shallower in junction depth than the other portions 13 in the source/drain diffusion regions 18, lateral variations also can be suppressed, compared with the deeper portions 13 in junction depth. Accordingly, since width variations in the lateral direction (channel direction) of the offset regions can be suppressed lower, a semiconductor storage device of high reliability can be formed. However, the source/drain diffusion regions may also be formed so as to overlap on the slope portions only by the impurity implantation for the formation of ordinary source/drain diffusion regions. In this case, however, the variation reduction effect for the width in the lateral direction (channel direction) is not produced, compared with the case where the extension portions are formed, but there is produced a working effect that the process is simplified.

As the manufacturing method for this semiconductor storage device, the manufacturing method of FIGS. 2A-2D described in the second embodiment may be used basically. However, as a characteristic step of this embodiment, a step for forming the extension portions and/or counter regions is added. Although FIGS. 4A-4C show a case where the extension portions alone are formed, the following description includes a case where the counter regions are formed, as well.

That is, as shown in FIG. 4A, the structure shown in FIG. 2C is first formed, and thereafter the extension portions 6 are formed so that a conductive type identical to that of the source/drain diffusion regions can be obtained, and this is done by performing impurity implantation with the injection energy lower than that for the source/drain diffusion regions. However, thermal treatment for activation of the impurities do not need to be done at this stage yet, and may be performed simultaneously with the later formation of the source/drain diffusion regions.

In this process, the extension portions 6, which are lower in injection energy than the other portions 13 in the source/drain diffusion regions 18 (see FIG. 4C), can be formed shallow in junction depth. As a result, lateral variations involved in the formation of the diffusion regions of the extension portions 6 can be suppressed to smaller ones than the lateral variations involved in the formation of the deeper-in-junction-depth portions 13, so that variations in the offset regions can also be suppressed to small ones. Therefore, particularly since variations in injection quantity of electric charge into the memory function bodies can be suppressed, a semiconductor storage device in which variations in device element characteristics are suppressed and which are high in reliability can be formed.

At this stage, if the impurity implantation for forming the counter regions is further performed so that a conductive type reverse to that of the source/drain diffusion regions can be obtained, then the counter regions can be formed. As in the formation of the extension portions, thermal treatment may be performed in later processes. However, the counter regions, which need to be formed inside the extension regions as shown in FIG. 1D, can be formed reliably inside by performing the implantation with an implantation angle larger than that for the extension portions.

Also, in the case where the counter regions alone are formed without forming the extension portions, there is formed a structure that the source/drain diffusion regions and the counter regions come into contact with each other.

Next, as shown in FIG. 4B, silicon nitride 17 is formed as the material of the charge retention parts in such a fashion that the recesses 50 are thereby buried. The method for forming the silicon nitride 17 may be given by the process described in the explanation of FIG. 2D of the second embodiment.

Next, as shown in FIG. 4C, memory function bodies 11 each composed of a charge retention part 31 and a first dielectric 32a are formed on opposite sides of the gate stack 8. The method for forming the memory function bodies 11 may be given by the process described in the explanation of FIG. 3 of the second embodiment.

Thus, a semiconductor storage device in which counter regions and/or extension portions are formed has been formed.

### Fourth Embodiment

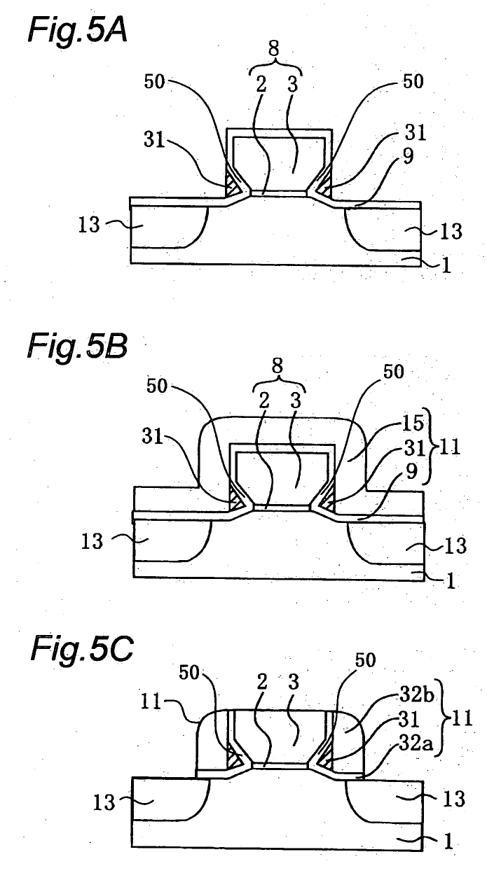

A semiconductor storage device of a fourth embodiment of the invention is explained in detail with reference to FIGS. 5A-5C.

The semiconductor storage element in this embodiment is, as shown in FIG. 5C, generally similar in construction to the semiconductor storage element of the second embodiment. However, this embodiment is characterized in that the charge retention parts 31 are limitedly formed so as to be housed in the recesses 50, respectively, so that the topmost position of each charge retention part 31 becomes lower than the topmost position of the gate electrode 3. As a result of this, as compared with the semiconductor storage element described in the second embodiment, the charge retention parts can be formed so as to be limited to vicinities of the place where hot carriers are generated, so that electrons injected by write operation can be erased more easily, making erase failures more unlikely to occur and making the reliability improved. Further, while the quantity of injected electric charge keeps unchanged, the volume of charge retaining portions in the memory function bodies for retaining electric charge is decreased, so that the quantity of electric charge per unit volume can be increased. Therefore, write/erase of electrons can be achieved efficiently, and a semiconductor storage device of high write/erase speed is provided.

Also, in this structure, the charge retention part 31 that forms part of the memory function body 11 and that is made of silicon nitride having the function of storing electric charge is sandwiched between the anti-dissipation dielectrics 32 (first dielectric 32a and second dielectric 32b). Therefore, dispersion of retained electric charge is suppressed, and a semiconductor storage device good at retention characteristic can be provided. Also, by providing a structure that the charge retention part 31 is sandwiched by the anti-dissipation dielectrics 32 (first dielectric 32a and second dielectric 32b), dispersion of electric charge injected in write operation into the gate electrode and other nodes is suppressed, so that the charge injection efficiency is enhanced, making higher-speed operation to be achievable.

The manufacturing method for this semiconductor storage device may be given basically by the manufacturing method of FIGS. 2A-2D described in the second embodiment. However, in this embodiment, the steps subsequent to the formation of the structure shown in FIG. 3, i.e. subsequent to the impurity implantation for the formation of the source/drain diffusion regions 13, are performed.

Thereafter, as shown in FIG. 5A, anisotropic etchback is further performed to remove portions of the silicon nitride (material of charge retention parts 31) present outside the recesses 50, by which a step for leaving silicon nitride within the recesses 50 is performed. Thus, a working effect of scale-down of the memory function bodies 11 can be obtained while a sufficient offset width is ensured. In the step of etching the memory function bodies 11, using isotropic etching is more preferable because scale-down in both height direction and width direction can be achieved at one time. Also, this etching is desirably performed under such conditions that the substances constituting the memory function bodies can be selectively etched while the materials of the gate electrode 3 and the semiconductor substrate 1 are hard to etch. For example, a wet etching process using hot phosphoric acid may be used.

However, in the case where a material identical to that of the semiconductor substrate 1 or the gate electrode 3 is used for the memory function bodies, i.e., in a typical case where the memory function bodies have polysilicon or silicon dots and where the semiconductor substrate is formed of silicon or the gate electrode is formed of polysilicon or in other like cases, sufficient selection ratios among those materials cannot be obtained, and when isotropic etching is performed with hydrogen fluoride used as an etchant as an example, polysilicon or silicon dots in the memory function bodies remain unetched. In such a case, it is appropriate that further oxidation is performed to oxidize etching residues so that etching with hydrogen fluoride is enabled, to remove the residues.

Next, as shown in FIG. 5B, a deposit dielectric film 15 is formed generally uniformly. As the deposit dielectric film, a film of good step coverage such as an HTO (High Temperature Oxide) or a film using CVD (Chemical Vapor Deposition) may appropriately be used. When an HTO is used, the film thickness may be about 10 nm to 100 nm.

Next, as shown in FIG. 5C, the deposit dielectric film 15 is etched by using etchback process, by which illustrated second dielectrics 32b formed of part of the deposit dielectric film 15 are formed as side walls. The deposit dielectric film 15 is anisotropically etched, by which memory function bodies 11 each composed of the first dielectric 32a, the charge retention part 31 and the second dielectric 32b are formed as side walls on opposite sides of the gate stack 8, respectively. This etching is desirably performed under such conditions that the deposit dielectric film 15 can be selectively etched and that the etching selection ratio to the semiconductor substrate 1 is a large one.

In addition, although described also in the second embodiment, the impurity implantation for the formation of the source/drain diffusion regions 13 may also be done before the formation of the charge retention parts 31, which is applicable also to this embodiment. However, in that case, an etching process for the silicon nitride 17 is done after the step of impurity implantation.

### Fifth Embodiment

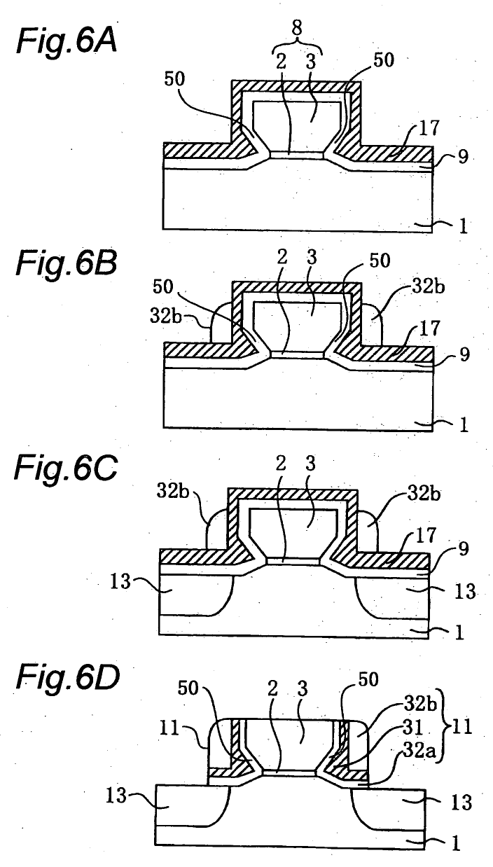

A semiconductor storage device of a fifth embodiment of the invention is explained with reference to FIGS. 6A-6D.

The semiconductor storage element of this embodiment is, as shown in FIG. 6D, generally similar in construction to the semiconductor storage element of the fourth embodiment. However, this embodiment is characterized in that the charge retention parts 31 are formed not only within the recesses 50 but also along entire side faces of the gate electrode 3 (via the first dielectrics 32a). The charge retention parts 31 may be formed so as to cover not the entirety but most part of the side faces of the gate electrode 3 as well.

In this structure, the charge retention part 31 that forms part of the memory function body 11 and that is made of silicon nitride having the function of storing electric charge is sandwiched between the anti-dissipation dielectrics 32 (first dielectric 32a and second dielectric 32b). Therefore, dispersion of retained electric charge is suppressed, and a semiconductor storage device good at retention characteristic can be provided. Also, by providing a structure that the charge retention part 31 is sandwiched by the anti-dissipation dielectrics 32 (first dielectric 32a and second dielectric 32b), dispersion of electric charge injected in write operation into the gate electrode and other nodes is suppressed, so that the charge injection efficiency is enhanced, making higher-speed operation to be achievable.

The manufacturing method for this semiconductor storage device may be given first by the manufacturing method of up to FIG. 2C described in the second embodiment. That is, the structure of FIG. 2C is formed in accordance with the method described in the second embodiment.

Thereafter, as shown in FIG. 6A, a first dielectric film 9 made of oxide is formed generally uniformly along the gate stack 8 and the exposed surfaces of the semiconductor substrate 1. This first dielectric film 9, for which oxide is used in this case, is preferably given by a film having a high withstand voltage, small leakage current and high reliability since it becomes a dielectric film through which electrons are passed. For example, an oxide film such as a thermal oxide film, an N₂O oxide film, an NO oxide film and the like is used as with the material of the gate insulator 2. Its film thickness of oxide is preferably 1 nm to 20 nm. Further, when this first dielectric film 9 is formed so thin that a tunneling current flows, the voltage required for injection or erase of electric charge can be made lower, thus allowing the power consumption to be reduced. A typical film thickness for that case is preferably 1 nm to 5 nm. In this case, by the formation of the first dielectric film 9, the silicon nitride 17 having the function of storing electric charge is in contact with the semiconductor substrate and the gate electrode via the dielectric film, so that leakage of the retained charge can be suppressed by this dielectric film. Thus, a semiconductor storage element good at charge retention characteristic and high in long-term reliability can be realized.

Next, silicon nitride 17 is deposited generally uniformly as the material of the charge retention parts in such a fashion that the recesses 50 are thereby buried. Although silicon nitride is used in this case, it is also possible to use, instead of silicon nitride, materials capable of retaining or inducing electric charge, for example, such a material as an oxynitride capable of retaining a substance having charge of electrons and holes and the like or an oxide having charge traps, or such a material as a ferroelectric capable of inducing electric charge to the surfaces of memory function bodies by polarization or other phenomena, or such a material as those having a structure that a floating substance like polysilicon or silicon dots capable of retaining electric charge is possessed in an oxide film. Also when these materials are used, similar working effects are produced. However, when an electrically conductive film is used, there is a need for disconnecting the charge retention parts 31, 31 on opposite (right-and-left) sides of the gate electrode from each other so as to prevent their short-circuiting to each other.

In this case, the film thickness of the silicon nitride 17 may be about 2 nm to 100 nm as an example.

Next, an unshown second dielectric film which forms at least part of an anti-dissipation dielectric and which is made of oxide is formed generally uniformly along exposed surfaces of the silicon nitride 17. As the second dielectric film, a film of good step coverage such as an HTO or a film using CVD may appropriately be used. When oxide is used as the second dielectric film, the film thickness may be about 5 nm to 100 nm. Also, the second dielectric film may be formed by film surface treatment of silicon nitride with heat treatment.

Next, the second dielectric film is anisotropically etched, by which second dielectrics 32b, 32b are formed on opposite sides of the gate stack 8 via the first dielectric film 9 and the silicon nitride 17 as shown in FIG. 6B. This etching is preferably performed under such conditions that the second dielectric film 9 can be selectively etched and that the etching selection ratio to the silicon nitride 17 is a large one.

Next, as shown in FIG. 6C, impurity implantation for formation of the source/drain diffusion regions 13 is performed. When the impurities are implanted over the silicon nitride 17 and the first dielectric film 9 as in this step, it is unnecessary to form any sacrifice oxide film for prevention of roughening of the semiconductor substrate surface. Therefore, a process simplification can be achieved, and a semiconductor storage device of low cost can be formed.

Alternatively, this impurity implantation step for forming the source/drain diffusion regions 13 may be executed after the formation of the memory function bodies 11. Furthermore, the step may be done during the formation of the memory function bodies 11, i.e., done over the first dielectric film 9 after the formation of the charge retention parts 31 by etching of the silicon nitride 17.

Next, as shown in FIG. 6D, the silicon nitride 17 is isotropically or anisotropically etched with the second dielectrics 32b used as an etching mask, by which charge retention parts 31 made of silicon nitride are formed on opposite sides of the gate stack 8 via the first dielectric film 9. In this case, the etching is preferably performed under such conditions that the silicon nitride 17 can be selectively etched and that the etching selection ratio to the first dielectric film 9 made of oxide and the second dielectrics 32b is a large one.

Next, the first dielectric film 9 is anisotropically etched, by which first dielectrics 32a are formed on the side walls of the gate stack 8. In this case, the etching is preferably performed under such conditions that the first dielectric film 9 can be selectively etched and that the etching selection ratio to the charge retention parts made of silicon nitride, the gate electrode 3 and the semiconductor substrate 1 is a large one.

Now, the memory function bodies 11 each composed of a first dielectric 32a, a charge retention part 31 and a second dielectric 32b have been formed.

However, there are some cases where the first dielectric 32a and the second dielectric 32b are both made of the same material like oxide, in which case a large etching selection ratio cannot be obtained. Therefore, in this case, there is a need for decreasing the etching amount in the formation of the second dielectrics 32b as required by taking into consideration the etching amount of the second dielectrics 32b in the etching of the first dielectric film.

In addition, there is a tendency that the charge retention parts 31 made of silicon nitride may also be etched at their upper portions more or less. However, this does not matter, in particular, because it leads to scale-down of the charge retention parts, and conversely a working effect of scale-down of the charge retention parts described in the fourth embodiment can be produced.

Further, in any of the cases where the impurity implantation for forming the source/drain diffusion regions 13 is performed over the silicon nitride 17 and the first dielectric film 9 explained in conjunction with FIG. 6C, and where the implantation is done over the first dielectric film 9, and where the implantation is done after the formation of memory function bodies, the source/drain diffusion regions 13 can be formed by thereafter adding a desired thermal treatment subsequent.

Further, the process from the structure of FIG. 6B to the structure of FIG. 6D may be carried out in one step (where the step for formation of the source/drain diffusion regions is not taken into consideration). That is, carrying out the process, which would ordinarily require three steps, in one step is enabled by performing anisotropic etching with the employment of such conditions that the first dielectric film 9, the second dielectric film and the silicon nitride 17 can all be etched and that the etching selection ratio to the material of the gate electrode 3 and the material of the semiconductor substrate 1 is a large one. Therefore, the number of process steps can be decreased, and the manufacturing cost can be reduced.

Now through the above steps, the memory function bodies 11 have been formed. A semiconductor storage device employing these memory function bodies 11 has the following working effects.

When electric charge is retained in the charge retention parts 31 of the memory function bodies 11, part of the channel formation region is strongly affected by electric charge, causing the drain current value to be changed. Thus, a semiconductor storage device that distinguishes the presence or absence of electric charge depending on the change of the drain current value is formed.

Also, the gate insulator 2 and the memory function bodies 11, because of their being disposed separate from each other, can be subjected to different types of scaling. Thus, a semiconductor storage device which suppresses the short-channel effect to be good at memory effect can be provided.

Also, since the charge retention parts 31 (made of silicon nitride) in the memory function bodies 11 are in contact with the semiconductor substrate 1 and the gate electrode 3 via the dielectric film, leakage of the retained charge can be suppressed by this dielectric film. As a result of this, a semiconductor storage device which is good at charge retention characteristic and high in long-term reliability is formed.

Also, in the case where an electrical conductor or semiconductor is used as the material of the memory function bodies, when a positive voltage is applied to the gate electrode, there occurs polarization within the memory function bodies, causing electrons to be induced to vicinities of the gate electrode side wall portions so that the electrons in the vicinities of the channel formation region are decreased. As a result of this, injection of electrons from the substrate or the source/drain diffusion regions can be accelerated, so that a semiconductor storage device fast in write speed and high in reliability can be formed.

### Sixth Embodiment

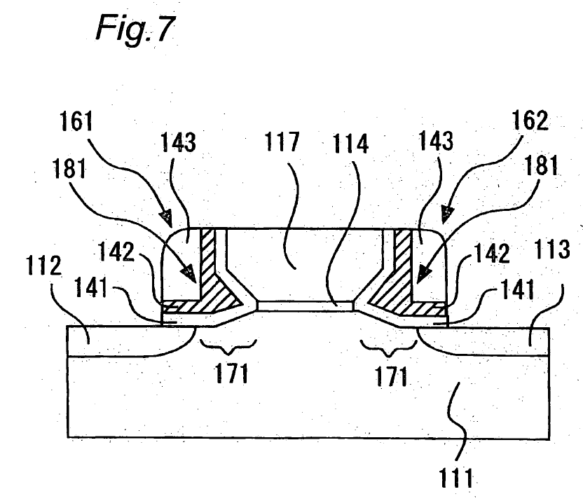

A semiconductor storage device of this embodiment is composed of a region where memory function bodies 161, 162 can retain electric charge (i.e., a region in which electric charge is stored and which may be a film having the function of retaining electric charge), and a region where electric charge is less allowed to escape (i.e., the region may be a film having a function of making electric charge less likely to escape). For example, the semiconductor storage device has an ONO (Oxide-Nitride-Oxide) structure as shown in FIG. 7. That is, silicon nitride 142 is sandwiched between silicon oxide 141 and silicon oxide 143, by which the memory function bodies 161, 162 are made up. It is noted that the silicon nitride fulfills the function of allowing electric charge to be retained. Also, the silicon oxides 141, 143 fulfill the role of a film having the function that electric charge stored in the silicon nitride is made unlikely to escape.

Also, the regions (silicon nitride 142) in the memory function bodies 161, 162 where electric charge can be retained are overlapped with diffusion regions 112, 113, respectively. The term, overlapping, means that at least portions of the region (silicon nitride 142) where electric charge can be retained are present on at least part of the diffusion regions 112, 113. Reference numeral 111 denotes a semiconductor substrate, 114 denotes a gate insulator, 117 denotes a gate electrode, and 171 denotes offset regions (between gate electrode and diffusion regions). Although not shown, topmost portion of the semiconductor substrate 111 under the gate insulator 114 forms a channel formation region.

Working effects by the overlapping between the regions 142 in the memory function bodies 161, 162 where electric charge can be retained and the diffusion regions 112, 113 are explained.

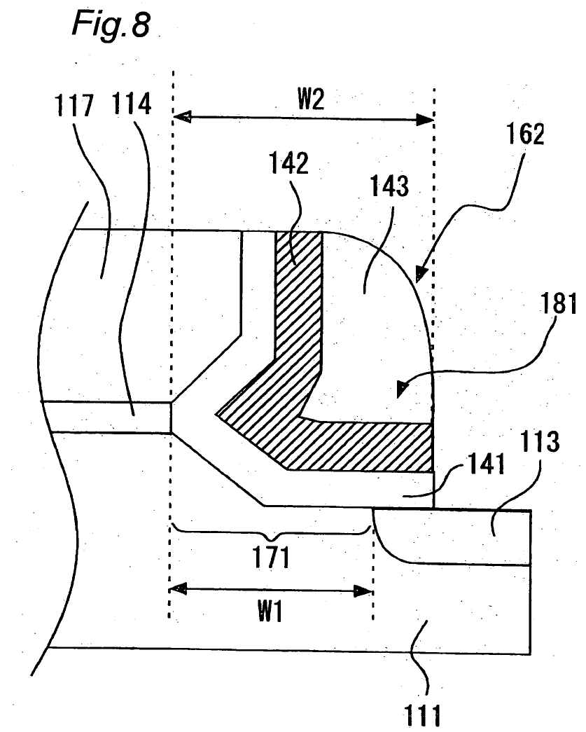

FIG. 8 is an enlarged view of the right-hand memory function body 162 and its peripheral portions shown in FIG. 7. Reference character W1 denotes an offset amount between the gate insulator 114 and the diffusion region 113. Also, W2 denotes the width of the memory function body 162 in a cross section in the gate length direction of the gate electrode. In addition, since one end of the silicon nitride 142 out of the memory function body 162 farther from the gate electrode 117 is coincident with one end of the memory function body 162 farther from the gate electrode 117, the width of the memory function body 162 is defined as W2. The amount of overlap between the memory function body 162 and the diffusion region 113 is expressed as (W2−W1). It is of particular importance that the silicon nitride 142 out of the memory function body 162 overlaps with the diffusion region 113, i.e., the relationship of W2>W1 is satisfied.

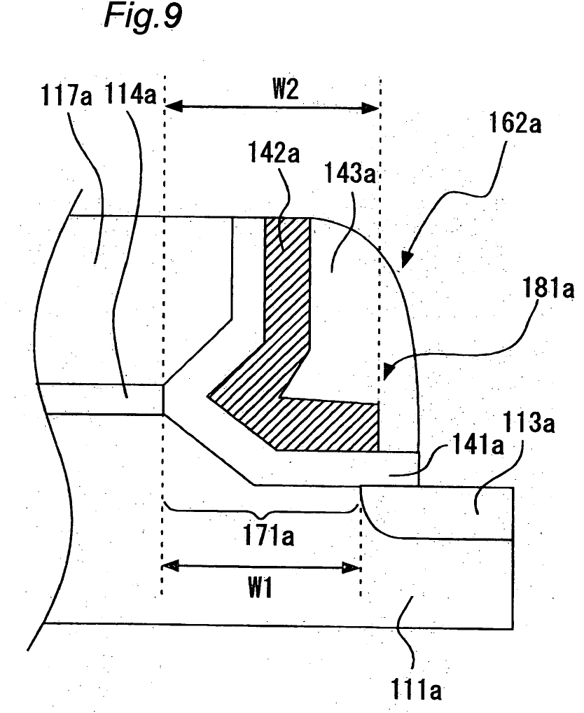

Further, when the one end of the silicon nitride 142a out of the memory function body 162a farther from the gate electrode is not coincident with the end of the memory function body 162a farther from the gate electrode as shown in FIG. 9, W2 may be defined as a range from the gate electrode end to the end of the silicon nitride 142a farther from the gate electrode. It is noted that component members in FIG. 9 are designated by reference numerals having ‘a’ added to the reference numerals of their corresponding component members in FIG. 8.

As the drain current in an erase state. (with holes accumulated) in the structure of FIG. 8, a sufficient current value can be obtained in the case of the configuration in which the silicon nitride 142 and the diffusion region 113 are overlapped with each other. However, in the configuration in which the silicon nitride 142 and the diffusion region 113 are not overlapped with each other, the value abruptly decreases as the silicon nitride 142 and the diffusion region 113 become farther away from each other, where the drain current value decreases to about an order of three digits with their distance 30 nm or so.

Since the drain current value is generally proportional to the read operation speed, the memory performance abruptly deteriorates as the distance between the silicon nitride 142 and the diffusion region 113 becomes larger. Meanwhile, in the range in which the silicon nitride 142 and the diffusion region 113 are overlapped with each other, the drain current decreases more gently. Therefore, it is preferable that at least part of the silicon nitride 142, which is a film having the function of retaining electric charge, and the source/drain diffusion region are overlapped with each other.

Based on the above-described results, with W2 fixed to 100 nm and with W1 set to 60 nm and 100 nm as design values, memory cell arrays were fabricated. The silicon nitride 142 and the diffusion regions 112, 113 are overlapped with each other by 40 nm as a design value in the case where W1 is 60 nm, while then are not overlapped with each other as design values in the case where W1 is 100 nm. As a result of measuring the read time of these memory cell arrays, the memory cell array with W1 set to 60 nm as a design value showed a 100 times faster read access time in a comparison between worst cases with variations take into consideration. For practical use, the read access time is preferably not more than 100 nanoseconds per bit, but it was found that this condition is far from achievable with W1=W2. Also, with considerations given even to variations in manufacture, a condition that (W2−W1>10 nm proved to be more preferable.

For reading of information stored in the memory function body 161 (region 181), it is preferable that with the diffusion region 112 set as a source electrode and the diffusion region 113 as a drain region, a pinchoff point is formed on one side within the channel formation region closer to the drain region. That is, it is preferable that the pinchoff point for reading information stored in one of the two memory function bodies is formed at a region within the channel formation region and closer to the other memory function body. As a result of this, information stored in the memory function body 161 can be detected with high sensitivity, regardless of storage state of the memory function body 162.

Meanwhile, in the case where information is stored only in one of the two memory function bodies or where the two memory function bodies are used in identical storage state, the pinchoff point does not necessarily need to be formed in reading.

In addition, although not shown in FIG. 7, it is preferable that a well region (P-type well for N-channel device) is formed on the surface of the semiconductor substrate 111. The formation of the well region makes it easier, while optimizing the impurity concentration of the channel formation region for memory operations (rewrite operation and read operation), to control the other electrical characteristics (withstand voltage, junction capacity, short-channel effect).

The memory function body, from the viewpoint of improving the memory retention characteristic, preferably includes a charge retention part having the function of retaining electric charge and a dielectric film. In this embodiment, the silicon nitride 142 having a level for trapping electric charge is used as the charge retention part while the silicon oxides 141, 143 having the function of preventing the dissipation of electric charge stored in the charge retention parts are used as dielectric films. The memory function bodies, by virtue of its including the charge retention parts and the dielectric films, makes it possible to prevent the dissipation of electric charge and improve the retention characteristic. Further, as compared with the case where the memory function body is composed of the charge retention part alone, the volume of the charge retention part can be decreased to a proper extent. By the decrease in the volume of the charge retention part, it becomes possible to restrict the move of the electric charge within the charge retention part and thereby suppress occurrence of characteristic changes due to the move of the electric charge during the retention of storage.

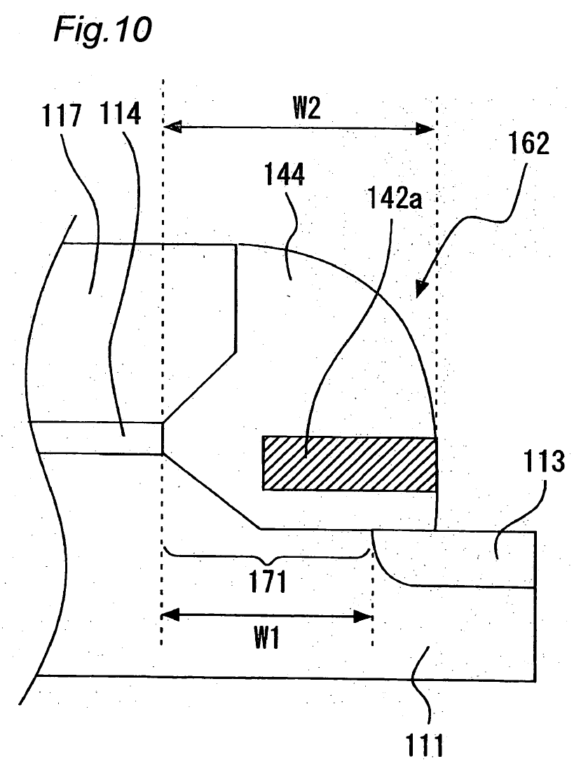

It is also preferable that the memory function body includes a charge retention part which is placed generally parallel to the surface of the gate insulator, that is, placed so that the top surface of the charge retention part in the memory function body is positioned equidistant from the top surface of the gate insulator. More specifically, as shown in FIG. 10, the charge retention part 142a of the memory function body 162 has a plane generally parallel to the surface of the gate insulator 114. In other words, the charge retention part 142a is preferably formed at a uniform height from the height corresponding to the surface of the gate insulator 114.

By the provision of the charge retention part 142a generally parallel to the surface of the gate insulator 114 in the memory function body 162, it becomes possible to effectively control the likeliness that an inverted layer may be formed at the offset region 171 depending on the amount level of electric charge stored in the charge retention part 142a, and therefore the memory effect can also be increased. Further, by the arrangement that the charge retention part 142a is generally parallel to the surface of the gate insulator 114, even when the offset amount (W1) has varied, changes in memory effect can be maintained relatively small, so that variations of the memory effect can be suppressed. Still, the move of electric charge toward the upper part of the charge retention part 142a, so that occurrence of characteristic changes due to the move of electric charge during the retention of storage can be suppressed.

Further, it is preferable that the memory function body 162 includes, as part of the anti-dissipation dielectric, a dielectric film (e.g., a portion of silicon oxide 144 on the offset region 171) that isolates the charge retention part 142a generally parallel to the surface of the gate insulator 114 and the channel formation region (or well region) from each other. By this dielectric film, the dissipation of electric charge stored in the charge retention part is suppressed, and a semiconductor storage device even better at retention characteristic can be obtained.

In addition, by controlling the film thickness of the charge retention part 142a and moreover controlling the film thickness of the dielectric film (portion of the silicon oxide 144 on the offset region 171) under the charge retention part 142a to a constant thickness, it becomes implementable to maintain the distance from the semiconductor substrate surface to the electric charge stored in the charge retention part to a generally constant distance. That is, the distance from the semiconductor substrate surface to the electric charge stored in the charge retention part can be controlled to within a range from a minimum film thickness value of the dielectric film under the charge retention part 142a to a sum of a maximum film thickness value of the dielectric film under the charge retention part 142a and a maximum film thickness value of the charge retention part 142a. As a result of this, it becomes possible to generally control the density of electric lines of force generated by the electric charge stored in the charge retention part 142a, thus allowing the memory effect of the semiconductor storage element to be quite small in variations.

### Seventh Embodiment

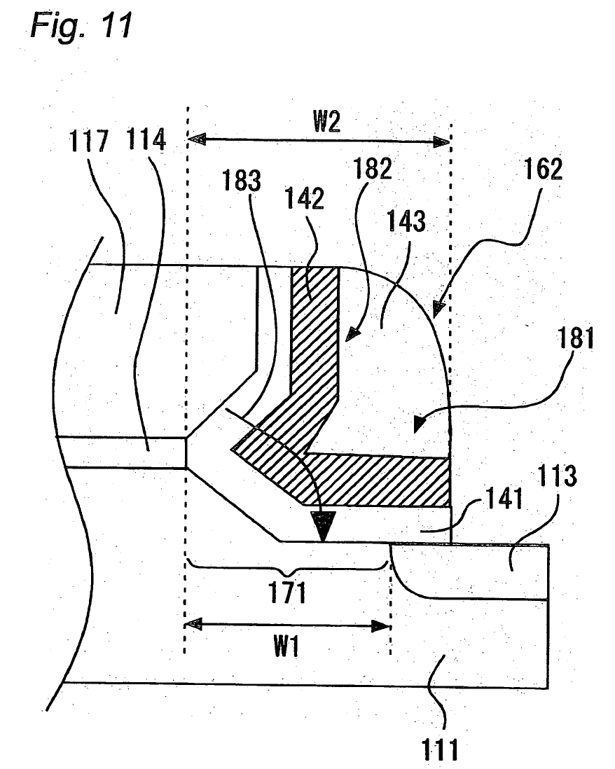

In this embodiment, the charge retention part 142 of the memory function body 162, as shown in FIG. 11, is so configured at a generally uniform film thickness as to be disposed generally parallel to the surface of the gate insulator 114 (arrow 181) and further generally parallel to the side face of the gate electrode 117 (arrow 182).

When a positive voltage is applied to the gate electrode 117, an electric line of force in the memory function body 162 passes twice through the silicon nitride 142 as shown by the arrow 183 (i.e., passes through portions of the silicon nitride 142 indicated by arrow 182 and arrow 181). It is noted that when a negative voltage is applied to the gate electrode 117, the direction of electric lines of force is reversed. In this case, the dielectric constant of the silicon nitride 142 is about 6, and the dielectric constant of the silicon oxides 141, 143 is about 4. Therefore, the effective dielectric constant of the memory function body 162 in the direction of the electric line of force 183 becomes larger than that in the case where only the charge retention part shown by the arrow 181 is present, thus allowing the potential difference between opposite ends of the electric line of force to be made smaller. That is, a large portion of the voltage applied to the gate electrode 117 is used to intensify the electric field in the offset region 171.

The injection of electric charge into the silicon nitride 142 in rewrite operation is due to the reason that generated electric charge is pulled in by the electric field in the offset region 171. Therefore, by the inclusion of the charge retention part shown by the arrow 182, electric charge to be injected into the memory function body 162 in rewrite operation is increased, so that the rewrite speed is increased.

In addition, when the part given by the silicon oxide 143 is given by silicon nitride as well, i.e., when the charge retention part is not uniform for the height corresponding to the surface of the gate insulator 114, the move of electric charge upward of the silicon nitride becomes heavier, causing the retention characteristic to be deteriorated.

More preferably, the charge retention part is formed of a high dielectric substance such as hafnium oxide, which has a very large dielectric constant, instead of silicon nitride for the same reason.

Further, preferably, the memory function bodies further include, as a portion of the anti-dissipation dielectric, a dielectric film (a portion of the silicon oxide 141 on the offset region 171) that isolates the charge retention part generally parallel to the surface of the gate insulator and the channel formation region (or well region) from each other. By this dielectric film, the dissipation of electric charge stored in the charge retention part is suppressed, so that the retention characteristic can be further improved.

Also, preferably, the memory function body further includes a dielectric film (a portion of the silicon oxide 141 in contact with the gate electrode 117) that isolates the gate electrode and the charge retention part extending along a direction generally parallel to the side face of the gate electrode from each other. By this dielectric film, changes in electrical characteristics that would occur due to injection of electric charge from the gate electrode into the charge retention part can be prevented, so that the reliability of the semiconductor storage device can be improved.

Further, preferably, the film thickness of the dielectric film under the charge retention part 142 (a portion of the silicon oxide 141 on the offset region 171) is controlled so as to be constant, and moreover the film thickness of the dielectric film placed on the surface of the gate electrode (a portion of the silicon oxide 141 in contact with the gate electrode 117) is controlled so as to be constant. Thus, leakage of electric charge stored in the charge retention part 142 can be prevented.

### Eighth Embodiment

This embodiment relates to an optimization of the distance among the gate electrode, the memory function bodies and the source/drain diffusion regions.

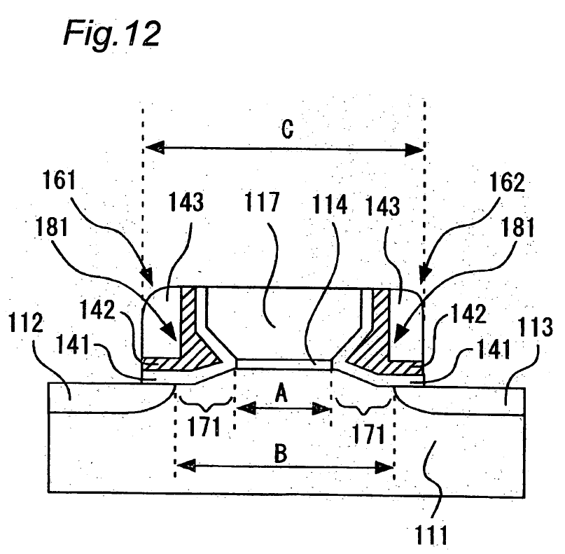

As shown in FIG. 12, reference character A denotes a gate electrode length in a cross section in the direction of the gate length, B denotes a distance between source/drain diffusion regions (channel length), and C denotes a distance from an end of one memory function body to an end of the other memory function body, i.e., a distance from an end (one side farther from the gate electrode) of a film having the function of retaining electric charge within one memory function body in a cross section in the gate length direction to an end (one side farther from the gate electrode) of a film having the function of retaining electric charge within the other memory function body.

First, it is preferable that B<C. An offset region 171 is present between the portion under the gate electrode 117 and the source/drain diffusion regions 112, 113 in the channel formation region. If B<C, then the degree of invertibility is effectively changed over the entire offset regions 171 by the electric charge stored in the memory function bodies 161, 162 (silicon nitride 142).

Also, if the gate electrode 117 and the source/drain diffusion regions 112, 113 are offset from each other, i.e., if A<B, then the degree of invertibility of the offset regions upon application of a voltage to the gate electrode is largely changed by the amount of charge stored in the memory function bodies, so that the memory effect is increased while the short-channel effect can be reduced. However, as far as the memory effect is developed, the offset regions 171 do not necessarily need to be present. Even when the offset regions 171 are absent, the memory effect can be developed in the memory function bodies 161, 162 (silicon nitride 142) if the impurity concentration of the source/drain diffusion regions 112, 113 is sufficiently low.

Thus, it is most preferable that A<B<C.

### Ninth Embodiment

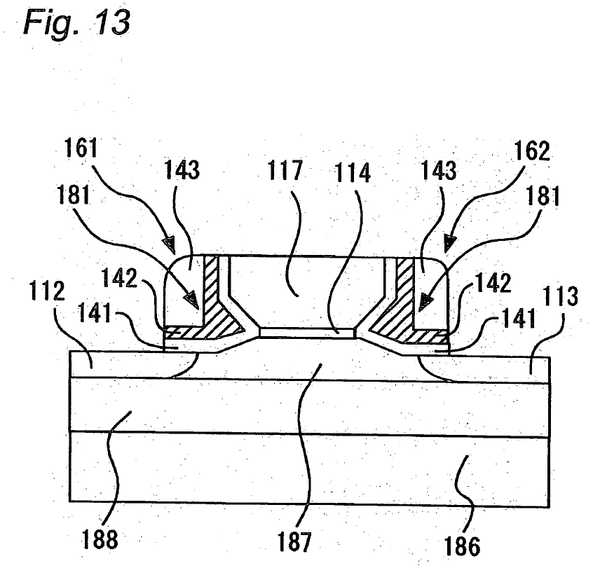

A semiconductor storage device of this embodiment is, as shown in FIG. 13, substantially similar in construction to the semiconductor storage device of the eighth embodiment, except that the semiconductor substrate is implemented by an SOI substrate.

In this semiconductor storage device, buried oxide 188 is formed on a semiconductor substrate 186, and further thereon an SOI layer is formed. Diffusion regions 112, 113 are formed in the SOI layer, and the region other than those is a body region 187.

Also by this semiconductor storage device, the same working effects as those of the semiconductor storage device of the eighth embodiment are produced. Further, the junction capacity between the diffusion regions 112, 113 and the body region 187 can be made remarkably small, so that enhancement in device speed and reduction in power consumption become achievable.

Further, the substrate floating effect unique to SOI substrates becomes more likely to be developed, so that the generation efficiency of hot electrons can be improved, allowing the write speed to be made faster.

### Tenth Embodiment

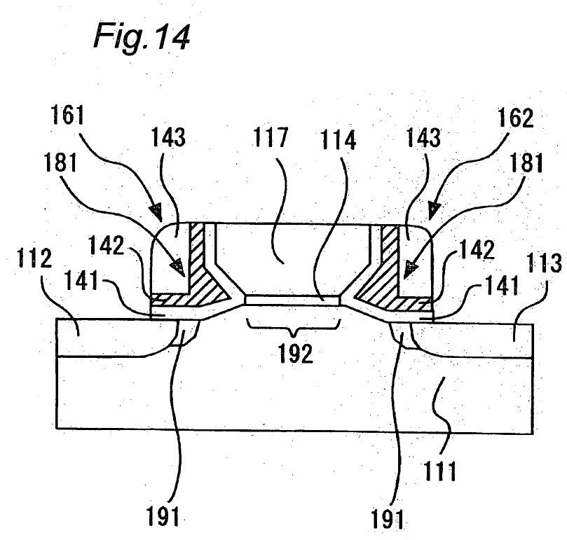

A semiconductor storage device of this embodiment is, as shown in FIG. 14, substantially similar in construction to the semiconductor storage device of the sixth embodiment, except that a P-type heavily doped region 191 is additionally provided in adjacency to the channel side of the N-type source/drain diffusion regions 112, 113.

That is, the concentration of impurities that give the P type in the P-type heavily doped region 191 (e.g., boron) is higher than the concentration of impurities that give the P type in the region 192. The P-type impurity concentration in the P-type heavily doped region 191 is properly about 5×10¹⁷ cm⁻³ to 1×10¹⁹ cm⁻³ as an example. Also, the P-type impurity concentration of the region 192 may be set to 5×10¹⁶ cm⁻³ to 1×10¹⁸ cm⁻³ as an example.

By the provision of the P-type heavily doped region 191 as shown above, the junction between the diffusion regions 112, 113 and the semiconductor substrate 111 becomes abrupt just under the memory function bodies 161, 162. Therefore, hot carriers are more likely to be generated in write and erase operations, so that the voltages for write operation and erase operation can be lowered, or that the speed of write operation and erase operation can be made faster. Further, since the region 192 is relatively lightly doped, the threshold value becomes low and the drain current becomes large in an erase state of the memory. Therefore, the read speed is improved. Consequently, there can be obtained a semiconductor storage device which is low in rewrite voltage, or high in rewrite speed, and fast in read speed.

Also, in FIG. 14, by provision of a P-type heavily doped region 191 at places near the source/drain diffusion regions and under the memory function bodies 161, 162 (i.e., not just under the gate electrode), the threshold value of the transistor as a whole increases to a considerable extent. The degree of this increase is far larger than that of the case where the P-type heavily doped region 191 is located just under the gate electrode. This difference becomes even larger when write charge (electrons for N-channel type transistors) is stored in the memory function body. On the other hand, when sufficient erase charge (holes for N-channel type transistors) is stored in the memory function body, the threshold value of the transistor as a whole decreases to a threshold value that is determined by the impurity concentration of the channel formation region (region 192) under the gate electrode. That is, the threshold value for erase operation does not depend on the impurity concentration of the P-type heavily doped region 191, while the threshold value for write operation is affected to a quite a large extent. Therefore, by the placement of the P-type heavily doped region 191 at places under the memory function bodies and near the source/drain diffusion regions, only the threshold value for write operation changes to a very large extent, so that the memory effect (difference in threshold value between write and read operations) can be remarkably increased.

### Eleventh Embodiment

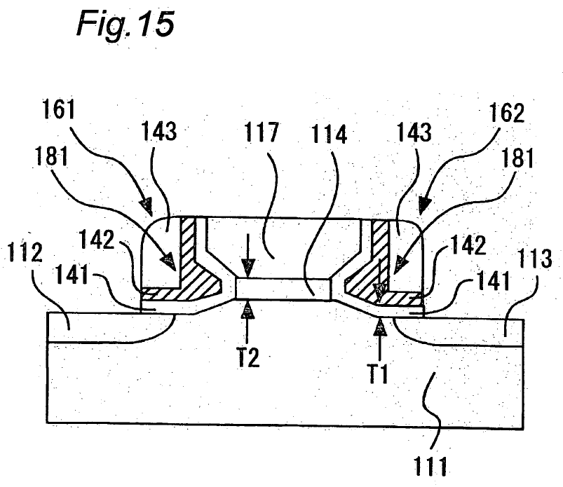

A semiconductor storage device of this embodiment is, as shown in FIG. 15, substantially similar in construction to the semiconductor storage device of the eighth embodiment, except that the thickness (T1) of the dielectric film for isolating the charge retention parts (silicon nitride 142) and the channel formation region or well region from each other is smaller than the thickness (T2) of the gate insulator.

For the gate insulator 114, there is a lower limit value of its thickness T2 in terms of requirement for the withstand voltage in the rewrite operation of the memory. However, the thickness T1 of the dielectric film may be set thinner than T2 regardless of the requirement for withstand voltage. With such a thinner thickness T1, it becomes easier to inject electric charge into the memory function bodies, so that the voltages for write operation and erase operation can be lowered, or that the speed of write operation and erase operation can be made faster.

Therefore, with the setting that T1<T2, the voltages for write operation and erase operation can be lowered, or that the speed of write operation and erase operation can be made faster, without lowering the withstand voltage performance of the memory, thus making it possible to further increase the memory effect.

In addition, the thickness T1 of the dielectric film is, more preferably, not less than 0.8 nm, which is such a limitative value that a uniformity by the manufacturing process or a certain level of film quality can be maintained, and that the retention characteristic is not considerably deteriorated.

### Twelfth Embodiment

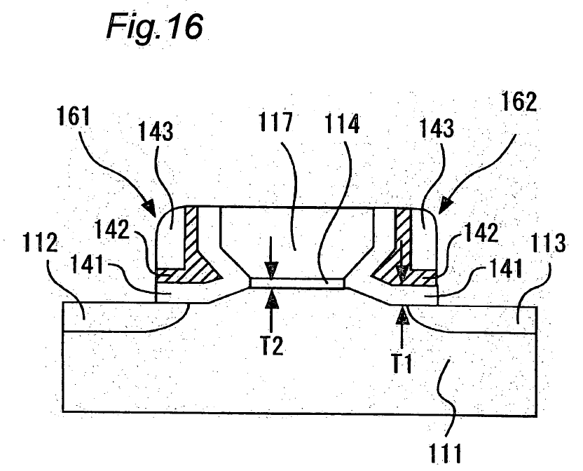

A semiconductor storage device of this embodiment is, as shown in FIG. 16, substantially similar in construction to the semiconductor storage device of the eighth embodiment, except that the thickness (T1) of the dielectric film that isolates the charge retention part (silicon nitride 142) and the channel formation region or well region from each other is thicker than the thickness (T2) of the gate insulator.

For the gate insulator 114, there is an upper limit value of its thickness T2 in terms of requirement for prevention of the short-channel effect of the device. However, the thickness T1 of the dielectric film may be set thicker than T2 regardless of the requirement for the short-channel effect. With such a thicker thickness T1, it becomes implementable to prevent the dissipation of electric charge stored in the charge storage regions and thereby improve the retention characteristic of the memory.

Accordingly, with the setting that T1>T2, it becomes possible to improve the retention characteristic without worsening the short-channel effect of the memory.

In addition, it is preferable that the thickness T1 of the dielectric film is not more than 20 nm in consideration of decreases in rewrite speed.

### Thirteenth Embodiment

A semiconductor storage device of this embodiment is composed of a memory area in which semiconductor storage elements of a semiconductor storage device of the invention are provided, a peripheral circuit section of a memory formed of common MOSFETs (MOS Field-Effect Transistors) having a normal structure, an MPU (Micro Processing Unit) or the like, and an SRAM (static RAM) section or the like (called logic circuit area).

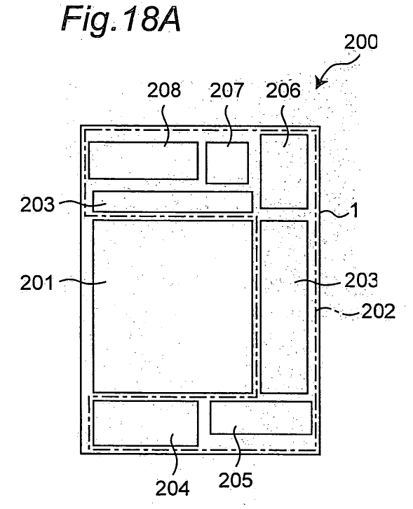

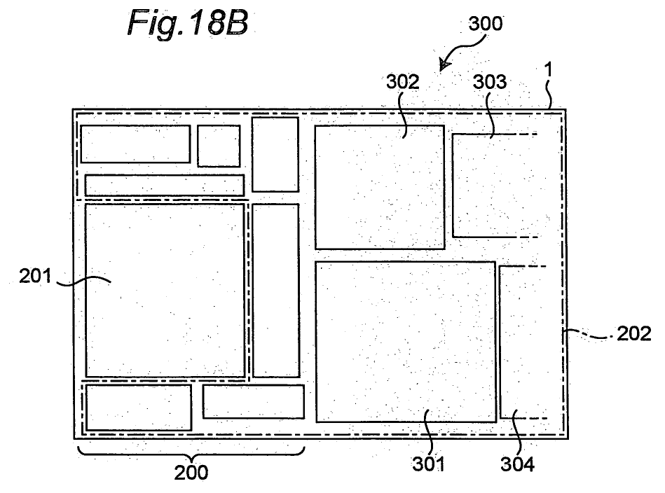

FIG. 18A shows a planar layout of a memory unit 200 which is an embodiment of the semiconductor device of the invention. In this memory unit 200, a logic circuit area 202 provided with semiconductor switching elements and a memory area 201 provided with semiconductor storage elements are arranged on one semiconductor substrate 1. In the memory area 201 is formed a memory cell array in which later-described semiconductor storage elements are disposed in an array configuration. In the logic circuit area 202 (surrounded by one-dot chain line) are formed peripheral circuits that can be made up by normal MOSFETs (field-effect transistors) such as a decoder 203, a write/erase circuit 204, a read circuit 205, an analog circuit 206, a control circuit 207 and various types of I/O circuits 208.

Further, in order that a storage device 300 of an information processing system for personal computers, portable telephones and the like is made up with one chip as shown in FIG. 18B, a logic circuit area 202 of a MPU (Micro-Processing Unit) 301, a cache (SRAM (static RAM)) 302, a logic circuit 303, an analog circuit 304 and the like in addition to the memory unit 200 needs to be disposed on the same semiconductor substrate 1.

The logic circuit part or the like in this embodiment refers to circuits or units which can be made up by using a logic circuit composed of common semiconductor switching elements as described above.

As can be understood from the procedure described in the second embodiment, the procedure for forming the semiconductor storage element is quite highly compatible with a known semiconductor switching element formation process. As apparent from FIGS. 2A-2D, the structure of the semiconductor storage element is close to that of a known semiconductor switching element except the swelling portion of the semiconductor substrate. The semiconductor switching element can be changed into the semiconductor storage element only by not forming the LDD (lightly doped drain) region with the use of, for example, a memory function body as the side wall spacer for the semiconductor switching element. Even if the side wall spacer of the semiconductor switching elements formed in the logic circuit part or the like has a function as the memory function body, the transistor performance is never impaired as far as the side wall spacer has an appropriate width and is operated within such a voltage range that rewrite operation does not occur. Accordingly, a common side wall spacer can be used to constitute the semiconductor switching element and the semiconductor storage element. Further, in order to compositely mount the semiconductor switching elements and semiconductor storage elements formed in the logic circuit part or the like, the LDD structure may be formed only in the memory peripheral circuit part, the logic circuit part, the SRAM part and the like. For the formation of the LDD structure, impurity implantation for the formation of the LDD region may be done after the gate electrode has been formed and before the material for forming the memory function body is deposited. Therefore, in the process of impurity implantation for the LDD formation, the semiconductor storage elements and the normal-structure MOSFETs constituting the memory peripheral circuit part, the logic circuit part, the SRAM part and the like can easily be compositely mounted only by masking the memory area with the photoresist. Further, when the SRAM is composed of the semiconductor storage element and the normal-structure MOSFETs that constitute the memory peripheral circuit part, the logic circuit part, the SRAM part and the like, it becomes easily achievable to compositely mount the semiconductor storage device, the logic circuit and the SRAM.

In the case where a higher voltage needs to be applied for the semiconductor storage element than is permitted in the logic circuit part, the SRAM part and the like, it will do only to add a high-voltage well-formation mask as well as a high-withstand-voltage gate-insulator formation mask to the standard MOSFET formation mask. Conventionally, the process of compositely mounting EEPROM (electrically erasable programmable ROM) and logic circuit part on one chip, largely differing from the standard MOSFET process, would involve considerably increased number of necessary masks and process man-hours. Therefore, it becomes possible to dramatically reduce the number of masks and the process man-hours, as compared with the conventional case where the EEPROM and such circuits as the memory peripheral circuit part, the logic circuit part and the SRAM part are compositely mounted. Thus, the cost of the chip on which the semiconductor switching elements of the memory peripheral circuit part, the logic circuit part, the SRAM part and the like and the semiconductor storage elements are compositely mounted is reduced. Further, since a high power supply voltage can be fed to the semiconductor storage element, the write/erase speed can be greatly improved. Furthermore, since a low power supply voltage can be fed to the logic circuit part, the SRAM part and the like, deteriorations of transistor characteristics due to breakdown of the gate insulator or the like can be suppressed, allowing the power consumption to be further reduced. Thus, it becomes possible to implement a semiconductor device having a logic circuit part of high reliability and semiconductor storage elements of remarkably fast write/erase speeds both of which are easily compositely mounted on the same substrate.

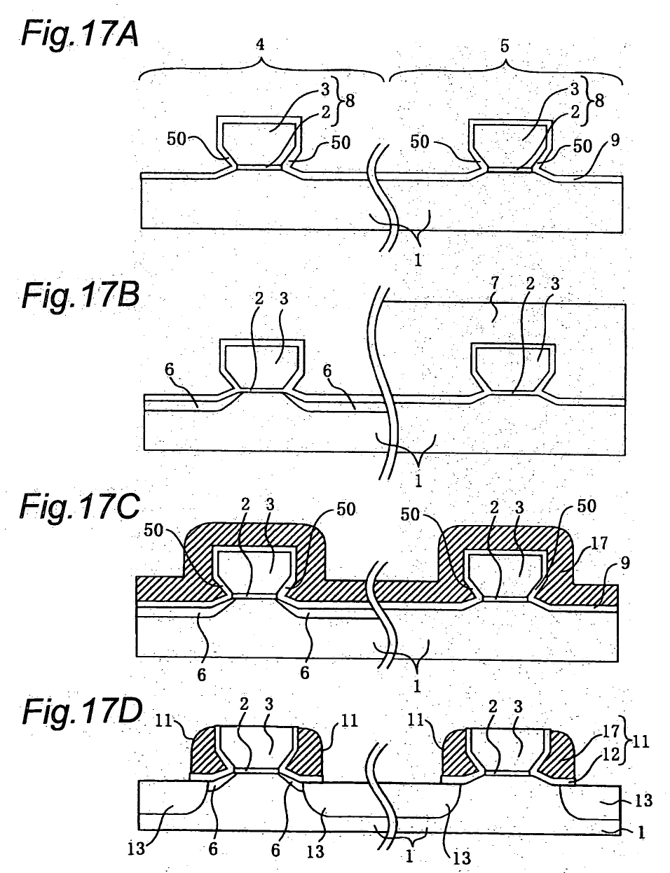

The manufacturing process for the semiconductor device of this embodiment is explained in detail with reference to FIGS. 17A-17D as follows.

In this embodiment, it is shown that individual devices of the semiconductor switching elements in the logic circuits or the like and the semiconductor storage elements can be simply formed both on an identical substrate at the same time without requiring any complex process. More specifically, it is shown that the semiconductor switching elements and the semiconductor storage elements can be fabricated simultaneously on one substrate by adding a photolithography step to the formation process of the semiconductor storage device formation described in the second embodiment to thereby provide one region where an LDD diffusion region is formed and another region where not.

The manufacturing process is explained below in order according to FIGS. 17A-17D. It is noted that in FIGS. 17A-17D, the left side corresponds to a semiconductor switching element in a logic circuit area 4 while the right side corresponds to a semiconductor storage element in a memory area 5.

For up to the step of forming a first dielectric film 9, steps similar to those of the second embodiment may be used. That is, as shown in FIG. 17A, the structure described in FIG. 2C is formed for both the logic circuit area 4 and the memory area 5.

Next, as shown in FIG. 17B, while the memory area 5 is kept covered with photoresist 7 serving as an implantation mask, impurities are ion-implanted, by which an LDD region 6 is formed only in the logic circuit area 4. In this case, the photoresist 7 is formed and the LDD region is not formed in the memory area 5. For this process, the impurity implantation is preferably done at an implantation angle larger than the implantation angle for the extension portions 6 explained in FIG. 4A because the LDD region can securely be formed so as to extend to under the gate electrode and overlap therewith. Also, by this step, an LDD region has been formed in the logic circuit area 4 where general semiconductor switching elements are to be formed while the LDD region 6 is not formed in the memory area 5. This photoresist is intended to block the implantation, and has only to be one which can be selectively removed and which may be a dielectric film such as silicon nitride. This step only is a special step that differs from the second embodiment, and the following steps afterwards may be the same steps as those of the second embodiment.

That is, as shown in FIG. 17C, silicon nitride 17 is formed by using the same step as in FIG. 2D of the second embodiment. Alternatively, the formation in this step may be done before the implantation for the formation of the LDD region or in a side wall formation step after performing the separation. In either case, the same effects are produced.

Further, as shown in FIG. 17D, memory function bodies 11 are formed by using the same steps as in FIG. 3 of the second embodiment. Further, up to the source/drain diffusion regions 13 are formed by using the same steps.

As a result of the above steps, a photolithography step is added to the steps for the formation of the semiconductor storage device described in the second embodiment, so that the region is divided into a region 4 where the LDD diffusion region is formed and another region 5 where not. Thus, the semiconductor switching elements and the semiconductor storage elements can be fabricated simultaneously on an identical substrate with simplicity and without requiring any complex process.

When electric charge is retained in the memory function bodies, part of the channel formation region is strongly affected by electric charge, causing the drain current value to be changed. Thus, a semiconductor storage element that distinguishes the presence or absence of electric charge depending on the change of the drain current value is formed.

By the placement of the gate stack 8 and the memory function bodies 11 separate from each other, it has become possible to compositely mount the semiconductor switching element and the semiconductor storage elements on one chip without involving any large process change or process man-hour increase, compared with standard MOSFET process. Therefore, the manufacturing cost for compositely mounting the memory area and the memory logic circuit part on one chip can be reduced to a large extent.

By forming on one identical substrate by a self-alignment like process the semiconductor storage element in which the gate electrode end and the source/drain regions are offset and the semiconductor switching element in the logic circuit area in which the gate electrode end and the source/drain regions are not offset, it becomes possible to compositely mount semiconductor storage elements having a high memory effect and semiconductor switching elements provided in the logic circuit area and having a high current-driving power, simply without requiring any complex process.

Further, according to this semiconductor storage element, since the 2-bit storage per transistor can be realized, the semiconductor-storage-element occupation area per bit can be reduced so that a large-capacity semiconductor storage element can be formed.

### Fourteenth Embodiment

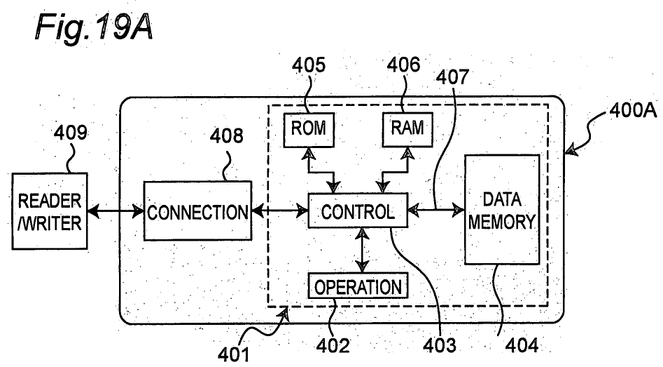

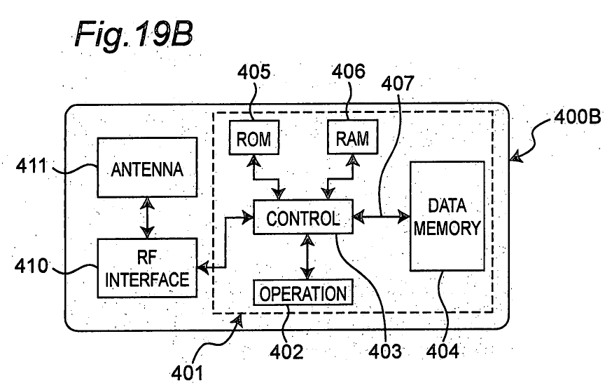

FIGS. 19A and 19B show the structure of each of IC cards 400A and 400B according to a fourteenth embodiment of the present invention.

The IC card 400A shown in FIG. 19A has a built-in MPU (Micro Processing Unit) 401 and a built-in connection section 408. The MPU 401 has a data memory section 404, an operation section 402, a control section 403, a ROM (Read Only Memory) 405, and a RAM (Random Access Memory) 406, all of these being formed in one chip. Programs for operating the MPU 401 are stored in the ROM 405. The RAM 406 is used as a work area and temporarily stores operation data. The MPU 401 has the semiconductor device according to the present invention. The constituent parts or sections 402, 403, 404, 405, 406, and 408 are connected with one another via lines (including a data bus and a power source line) 407. When the IC card 400A is placed in position in the reader/writer 409, the connection section 408 and the reader/writer 409 are connected to each other, so that the IC card 400A is energized and data exchange is performed.

The IC card 400A is characterized in that the MPU 401 incorporates the data memory section 404 and that the semiconductor switching elements and the semiconductor storage elements are placed together in one semiconductor chip.

The aforementioned semiconductor storage elements that enable the reduction of production costs are used in the data memory section 404. These storage elements are easy to miniaturize and allow two-bit operations. This facilitates reduction of the area of a memory cell array having such storage elements arrayed, and the memory cell array can be fabricated at reduced cost. Use of such a memory cell array in the data memory section 404 of the IC card 400A would reduce the cost of the IC card.

Further, because the MPU 401, which incorporates the data memory section 404, is formed in one chip, the production cost of the IC card can be largely reduced.

Further, because the MPU 401 has the semiconductor device according to the present invention, more specifically, the data memory section 404 uses the semiconductor storage elements and other circuits use the semiconductor switching elements, the fabrication process of the IC card is considerably simplified, as compared with a case in which the data memory section 404 uses flash memories. The reason for that is that the fabrication process for the semiconductor storage elements in the data memory section 404 is very similar to the fabrication process for the semiconductor switching elements in the logic circuits (i.e., operation section 402 and control section 403), so that it is very easy to place those storage elements and switching elements on one chip in a composite manner. Thus, incorporation of the data memory section 404 in the MPU 401 on one chip leads to a considerable cost reduction.

The ROM 405 may be constructed of the above-described semiconductor storage elements. This makes it possible to externally rewrite the ROM 405, which brings about remarkable increase of the functions of the IC card. Because the above semiconductor storage elements are easy to miniaturize and allow two-bit operations, substituting these semiconductor storage elements for the memory cells of the masked ROM would hardly cause increase of a chip area. Also, the process for forming the semiconductor storage elements is almost the same as the general CMOS forming process, which facilitates mixed-placing of the semiconductor storage elements with the logic circuit.

Referring next to FIG. 19B, the IC card 400B incorporates an MPU section 401, an RF interface section 410, and an antenna section 411. The MPU section 401 contains a data memory section 404, an operation section 402, a control section 403, a ROM 405, and a RAM 406, all of these being formed in one chip. The sections 402, 403, 404, 405, 406, 410, and 411 are connected to one another via lines (including a data bus and a power source line) 407.

The IC card 400B of FIG. 19B is different from the IC card 400A of FIG. 19A in that the IC card 400B is of non-contact type. Consequently, the control section 403 is connected not to the connection section but to the antenna section 411 via the RF interface section 410. The RF interface section 410 has a function of communicating with external equipment and a power collection function. The RF interface section 410 has a function of commutating high-frequency signals transmitted from the antenna section 411 and feeding power, and a function of modulating and demodulating signals. It is noted that the RF interface section 410 and the antenna section 411 may be placed together with the MPU 401 in one chip.

Since the IC card 400B is of non-contact type, it becomes possible to prevent electrostatic destruction which would occur through the connection section. Also, the IC card does not necessarily need to have a close contact with an external apparatus, which makes freedom of applications large. In addition, the semiconductor storage elements constituting the data memory section 404 each operate at low supply voltage (approx. 9V), compared with conventional flash memory cells (supply voltage of approx. 12V), which enables downsizing of the circuit of the RF interface section 410 and enables cost reduction.

### Fifteenth Embodiment

The semiconductor device of the present invention is applicable to battery-driven portable electronic equipment, especially to handheld terminals or personal digital assistances (PDAs). The portable electronic equipment include, for example, PDAs, mobile phones, game machines.

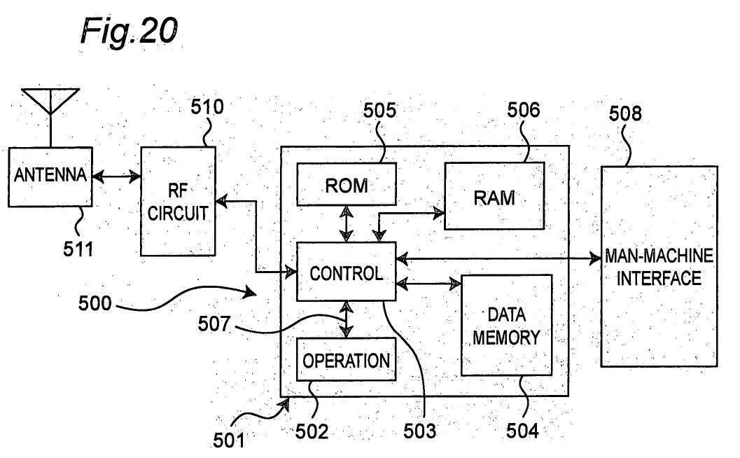

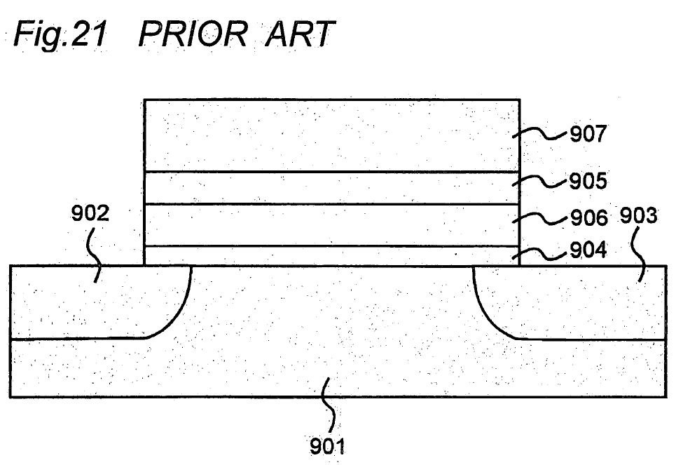

FIG. 20 shows a block diagram of a mobile phone 500 according to fifteenth embodiment of the present invention.

The mobile phone 500 incorporates an MPU section 501, a man-machine interface section 508, an RF circuit section 510, and an antenna section 511. The MPU section 501 has a data memory section 504, an operation section 502, a control section 503, a ROM 505, and a RAM 506, all of these being formed in one chip. Programs for operating the MPU 501 are stored in the ROM 505. The RAM 506 is used as a work area and temporarily stores operation data. The semiconductor device according to the present invention is incorporated in the MPU 501. The constituent parts or sections 502, 503, 504, 505, 506, 508, 510 and 511 are connected with one another via lines (including a data bus and a power source line) 507.

The mobile phone 500 is characterized in that the MPU 501 incorporates the data memory section 504 and that the semiconductor switching elements and the semiconductor storage elements are placed together in one semiconductor chip.

The aforementioned semiconductor storage elements that enable the reduction of production costs are used in the data memory section 504. These storage elements are easy to miniaturize and allow two-bit operations. This facilitates reduction of the area of a memory cell array having such storage elements arrayed, and the memory cell array can be fabricated at reduced cost. Use of such a memory cell array in the data memory section 504 of the mobile phone 500 would reduce the cost of the mobile phone.

Further, because the MPU 501, which incorporates the data memory section 504, is formed in one chip, the production cost of the mobile phone can be largely reduced.

Further, because the MPU 501 has the semiconductor device according to the present invention, more specifically, the data memory section 504 uses the semiconductor storage elements and other circuits use the semiconductor switching elements, the fabrication process is considerably simplified, as compared with a case in which the data memory section 504 uses flash memories. The reason for that is that the fabrication process for the semiconductor storage elements in the data memory section 504 is very similar to the fabrication process for the semiconductor switching elements in the logic circuits (i.e., operation section 502 and control section 503), so that it is very easy to place those storage elements and switching elements on one chip in a composite manner. Thus, incorporation of the data memory section 504 in the MPU 501 and placement thereof on one chip leads to a considerable cost reduction.

The ROM 505 may be constructed of the above-described semiconductor storage elements. This makes it possible to externally rewrite the ROM 505, which brings about remarkable increase of the functions of the mobile phone. Because the above semiconductor storage elements are easy to miniaturize and allow two-bit operations, substituting these semiconductor storage elements for the memory cells of the masked ROM would hardly cause increase of a chip area. Also, the process for forming the semiconductor storage elements is almost the same as the general CMOS forming process, which facilitates mixed-placement of the semiconductor storage elements and the logic circuit in one chip.

As is apparent from above, application of the semiconductor device of the present invention to a portable electronic device as typified by the mobile phone 500 contributes to a reduction in production cost of a control circuit of the electronic device and hence in cost of the portable electronic device itself, or contributes to an increase in number of the semiconductor storage elements included in such a control circuit so as to improve the overall function of the portable electronic equipment.

The invention being thus described, it will be obvious that the same may be varied in many ways. Such variations are not to be regarded as a departure from the spirit and scope of the invention, and all such modifications as would be obvious to one skilled in the art are intended to be included within the scope of the following claims.

1. A semiconductor storage device comprising:
a field effect transistor having a gate electrode spaced from a semiconductor substrate having a surface by a gate insulator and a pair of source/drain diffusion regions formed on the semiconductor substrate surface on opposite sides of the gate electrode, wherein
recesses are formed between opposite side portions of the gate electrode and the semiconductor substrate surface so as to be increasingly widening in cross section in a direction away from a centerline of the gate electrode, and
memory function bodies each comprising a charge retention part made of a material having a function of storing electric charge, and an anti-dissipation dielectric having a function of preventing dissipation of stored electric charge, are formed on opposite sides of the gate electrode in such a fashion that the recesses are thereby buried.

2. The semiconductor storage device as claimed in claim 1, wherein
the surface of the semiconductor substrate has a flat portion which is opposed to a bottom face of the gate electrode via the gate insulator, slope portions which adjoin opposite sides of the flat portion with respect to a gate length direction to form part of the recesses, and bottom face portions each of which adjoins an outer side of the slope portion.

3. The semiconductor storage device as claimed in claim 1, wherein
spaces are provided between the bottom face of the gate electrode and the source/drain diffusion regions with respect to the gate length direction.

4. The semiconductor storage device as claimed in claim 2, wherein
a side face of the gate electrode has a flat portion generally perpendicular to a surface of the gate insulator, and a slope portion which adjoins an underside of this flat portion to form part of the recesses, and
the anti-dissipation dielectric includes a first dielectric which covers the flat portion and the slope portion of the side face of the gate electrode as well as the slope portions and the bottom face portions of the semiconductor substrate surface, at a substantially uniform film thickness, in such a manner that the charge retention part and the gate electrode, as well as the charge retention part and the semiconductor substrate, are thereby isolated from each other, respectively.

5. The semiconductor storage device as claimed in claim 1, wherein
at least part of the charge retention part is overlapped with part of the source/drain diffusion regions.

6. The semiconductor storage device as claimed in claim 1, wherein.
The charge retention part has a portion generally parallel to the surface of the gate insulator.

7. The semiconductor storage device as claimed in claim 1, wherein
a side face of the gate electrode has a flat portion generally perpendicular to a surface of the gate insulator, and a slope portion which adjoins an underside of this flat portion to form part of the recesses, and
the charge retention part includes a portion extending generally parallel to the flat portion of the side face of the gate electrode.

8. The semiconductor storage device as claimed in claim 1, wherein
a thickness of a portion of the anti-dissipation dielectric that isolates the charge retention part and the semiconductor substrate from each other is thinner than a film thickness of the gate insulator and not less than 0.8 nm.

9. The semiconductor storage device as claimed in claim 1, wherein
a thickness of a portion of the anti-dissipation dielectric that isolates the charge retention part and the semiconductor substrate from each other is thicker than a film thickness of the gate insulator and not more than 20 nm.

10. The semiconductor storage device as claimed in claim 3, wherein
at least part of the source/drain diffusion regions is disposed in the slope portion of the semiconductor substrate surface.

11. The semiconductor storage device as claimed in claim 3, wherein
inside the pair of source/drain diffusion regions, counter regions which are doped more heavily than a channel formation region located just under the bottom face of the gate electrode are formed with a conductive type reverse to that of the source/drain diffusion regions.

12. The semiconductor storage device as claimed in claim 3, wherein
the source/drain diffusion regions each have an extension portion on one side thereof on which the channel formation region is present, and a junction depth of the extension portion is shallower than a junction depth of portions other than the extension portion.

13. The semiconductor storage device as claimed in claim 12, wherein
a impurity concentration of the extension portion is lower than a impurity concentration of portions of the source/drain diffusion regions other than the extension portion.

14. The semiconductor storage device as claimed in claim 3, wherein
the charge retention part of the memory function bodies is accommodated in the recesses.

15. A semiconductor device comprising:
a memory area having a semiconductor storage element and a logic circuit area having a semiconductor switching element, both the memory area and the logic circuit area being provided on a semiconductor substrate, wherein
the semiconductor storage element and the semiconductor switching element are implemented, respectively, by field effect transistors each having a gate electrode and a pair of source/drain diffusion regions formed on portions of a semiconductor substrate surface corresponding to opposite sides of the gate electrode,
in either of the semiconductor storage element and the semiconductor switching element, recesses are formed so as to be increasingly widening in cross section in a direction away from a centerline of the gate electrode, and memory function bodies each of which is composed of a charge retention part made of a material having a function of storing electric charge and an anti-dissipation dielectric having a function of preventing dissipation of stored electric charge are formed on opposite sides of the gate electrode in such a fashion that the recesses are thereby buried,
the semiconductor storage element is so constituted as to be capable of, upon application of a voltage to the gate electrode, changing an amount of a current flowing from one of the source/drain diffusion regions to the other of the source/drain diffusion regions depending on a level of electric charge retained in the charge retention part, and
the semiconductor switching element is so constituted as to perform switching operation regardless of the level of electric charge retained in the charge retention part.

16. An IC card which is equipped with the semiconductor storage device as defined in claim 1.

17. An IC card which is equipped with the semiconductor device as defined in claim 13.

18. Portable electronic equipment which is equipped with the semiconductor storage device as defined in claim 1.

19. Portable electronic equipment which is equipped with the semiconductor device as defined in claim 13.

20. A method for manufacturing a semiconductor storage device, comprising, in forming a semiconductor storage element constituted of a field effect transistor, the steps of:
forming a gate electrode on a semiconductor substrate surface via a gate insulator;
forming bird's beak dielectric films, which are increasingly widening in cross section in a direction away from a centerline of the gate electrode, between opposite side portions of the gate electrode and the semiconductor substrate surface, respectively;
removing the bird's beak dielectric films to thereby form recesses, which are increasingly widening sideways in cross section in the direction away from the centerline of the gate electrode, at places from which the bird's beak dielectric films have been removed;
forming memory function bodies on opposite sides of the gate electrode in such a fashion that the recesses are thereby buried, each of the memory function bodies being composed of a charge retention part made of a material having a function of storing electric charge and an anti-dissipation dielectric having a function of preventing dissipation of stored electric charge; and
with the gate electrode and the memory function bodies used as a mask, implanting impurities to portions of the semiconductor substrate surface corresponding to opposite sides of the mask to thereby form a pair of source/drain diffusion regions.

21. The semiconductor storage device manufacturing method as claimed in claim 20, wherein
the step of forming the memory function bodies include the steps of:
forming a first dielectric film which forms at least part of the anti-dissipation dielectric at a substantially uniform film thickness along the gate electrode and an exposed surface of the semiconductor substrate between which the recesses are formed;
forming silicon nitride as a material of the charge retention part on the exposed surface of the first dielectric film in such a manner that the recesses are thereby buried; and
etching the silicon nitride and the first dielectric film on opposite sides of the gate electrode so that the memory function bodies are left on opposite sides of the gate electrode, respectively.

22. The semiconductor storage device manufacturing method as claimed in claim 21, wherein
in the step of etching the silicon nitride and the first dielectric film, portions of the silicon nitride other than the recesses are removed so that portions of the silicon nitride present in the recesses are left.

23. A semiconductor device manufacturing method in which semiconductor storage elements each constituted of a field effect transistor are formed in a memory area set on a semiconductor substrate while semiconductor switching elements each constituted of a field effect transistor are formed in a logic circuit area set on the semiconductor substrate, the method comprising the steps of:
forming a gate electrode on portions of a semiconductor substrate surface corresponding to the memory area and the logic circuit area each via a gate insulator;
in both the memory area and the logic circuit area, forming bird's beak dielectric films, which are increasingly widening in cross section in a direction away from a centerline of the gate electrode, between opposite side portions of the gate electrode and the semiconductor substrate surface, respectively, and removing the bird's beak dielectric films to thereby form recesses, which are increasingly widening in cross section in the direction away from the centerline of the gate electrode, at places from which the bird's beak dielectric films have been removed;
introducing impurities of a first conductive type into the logic circuit area with the gate electrode used as a mask while a mask is provided so that the impurities are not introduced into the memory area, thereby forming in the logic circuit a first doped region which forms part of source/drain diffusion regions;
in both the memory area and the logic circuit area, forming memory function bodies on opposite sides of the gate electrode in such a fashion that the recesses are thereby buried, each of the memory function bodies being composed of a charge retention part made of a material having a function of storing electric charge and an anti-dissipation dielectric having a function of preventing dissipation of stored electric charge; and
with the gate electrode and the memory function bodies used as a mask, implanting impurities of the first conductive type, to each of the memory area and the logic circuit area to thereby form a second doped region which forms at least part of the source/drain diffusion regions.

24. A semiconductor storage device comprising:
a field effect transistor including a semiconductor substrate having a surface, a gate insulator formed on the semiconductor substrate, a gate electrode formed on the gate insulator and having a first end having a tapered portion adjacent the gate insulator and a pair of source/drain diffusion regions formed on first and second opposite sides of the gate electrode, and
memory function bodies including a charge retention part and an anti-dissipation dielectric formed on the first and second opposite sides of the gate electrode and covering the tapered portion.

25. The semiconductor storage device of claim 24 wherein said semiconductor substrate includes a projection having a first surface, said gate insulator being formed on said projection first surface, and first and second sloped surfaces extending away from said projection first surface and from said gate electrode.

26. The semiconductor storage device of claim 25 wherein said first sloped surface and said tapered portion of the gate electrode define a recess and wherein one of said memory function bodies fills said recess.

27. A method for manufacturing a semiconductor storage device comprising a semiconductor storage element including a field effect transistor comprising the steps of:
forming a gate insulator on a semiconductor substrate;
forming a gate electrode on the gate insulator;
thermally oxidizing a portion of the gate electrode and a portion of the semiconductor substrate adjacent the gate electrode to form a dielectric film extending into a space between the gate electrode and the semiconductor substrate;
removing the dielectric film;
forming memory function bodies on opposite sides of the gate electrode extending into and filling the space between the gate electrode and the semiconductor substrate, each of the memory function bodies including a charge retention part and an anti-dissipation dielectric part; and
with the gate electrode and the memory function bodies used as a mask, implanting impurities to the semiconductor substrate surface on opposite sides of the mask to form a pair of source/drain diffusion regions.
